(19) United States
(12) Patent Application Publication
(10) Pub. No.: US 2012/0273764 A1
(43) Pub. Date: Nov. 1, 2012

(54) COMPOSITION FOR ORGANIC PHOTOELECTRIC DEVICE, ORGANIC PHOTOELECTRIC DEVICE USING THE SAME, AND DISPLAY DEVICE INCLUDING THE SAME

(75) Inventors: Eun-Sun YU, Uiwang-si (KR); Hyung-Sun KIM, Uiwang-si (KR); Ho-Jae LEE, Uiwang-si (KR); Eui-Su KANG, Uiwang-si (KR); Young-Sung PARK, Uiwang-si (KR); Mi-Young CHAE, Uiwang-si (KR); Young-Hoon Kim, Uiwang-si (KR); Ja-Hyun KIM, Boryeong-city (KR)

(73) Assignee: CHEIL INDUSTRIES, INC., Gumi-si (KR)

(21) Appl. No.: 13/463,366

(22) Filed: May 3, 2012

Related U.S. Application Data
(63) Continuation of application No. PCT/KR2010/007546, filed on Oct. 29, 2010.

(30) Foreign Application Priority Data
Nov. 3, 2009 (KR) 10-2009-0105574

(51) Int. Cl. H01L 51/54; H01L 51/46; C09K 3/00

(52) U.S. Cl. 257/40; 252/501.1; 257/E51.018; 257/E51.012

(57) ABSTRACT

A composition for an organic photoelectric device, the composition including a first host compound including substituents represented by the following Chemical Formulas 1 to 3 sequentially combined; and a second host compound represented by the following Chemical Formula 4,

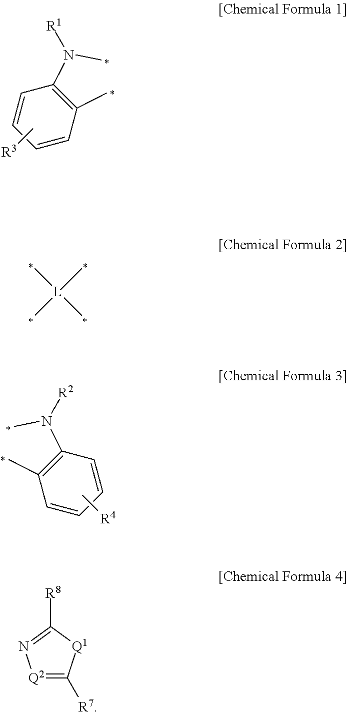

### CROSS-REFERENCE TO RELATED APPLICATION

This application is a continuation of pending International Application No. PCT/KR2010/007546, entitled “Composition for Organic Photoelectric Device, Organic Photoelectric Device Using the Same and Display Device Comprising the Same,” which was filed on Oct. 29, 2010, the entire contents of which are hereby incorporated by reference.

### BACKGROUND

1. Field

Embodiments relate to a composition for an organic photoelectric device, an organic photoelectric device using the same, and a display device including the same.

2. Description of the Related Art

A photoelectric device is, in a broad sense, a device for transforming photo-energy to electrical energy, and conversely, for transforming electrical energy to photo-energy. As examples, the organic photoelectric device includes an organic light emitting diode (OLED), a solar cell, a transistor, and the like. Particularly, an organic light emitting diode has recently drawn attention due to the increase in demand for flat panel displays.

When current is applied to an organic light emitting diode, holes are injected from an anode and electrons are injected from a cathode, then injected holes and electrons move to each hole transport layer (HTL) and electron transport layer (ETL) and recombined to a light emitting exciton in an emission layer. The light emitting excitons generate lights while shifting to a ground state. The light emission material may be classified as a fluorescent material including singlet excitons and a phosphorescent material including triplet excitons according to light emitting mechanism. The fluorescent and phosphorescent materials may be used for a light emitting source of an organic light emitting diode.

When electrons are transported from the ground state to the exited state, a single exciton undergoes non-light emitting transition to a triplet exciton through intersystem crossing and the triplet exciton is transited to the ground state to emit light. Herein, such a light emission refers to phosphorescent emission. When the triplet exciton is transited, it cannot directly transit to the ground state. Therefore, it is transited to the ground state after the electron spin is flipped. Therefore, a half-life (light emitting time, lifetime) of phosphorescent emission is longer than that of fluorescent emission.

When holes and electrons are recombined to produce a light emitting exciton, three times triplet light emitting excitons are produced compared to the amount of the singlet light emitting excitons. A fluorescent material has 25% of the singlet-exited state and a limit in luminous efficiency. On the other hand, a phosphorescent material can utilize 75% of the triplet exited state and 25% of the singlet exited state, so it can theoretically reach 100% of the internal quantum efficiency. Accordingly, the phosphorescent light emitting material has advantages of accomplishing around four times more luminous efficiency than the fluorescent light emitting material.

### SUMMARY

Embodiments are directed to a composition for an organic photoelectric device, the composition including a first host compound including substituents represented by the following Chemical Formulas 1 to 3 sequentially combined, and a second host compound represented by the following Chemical Formula 4,

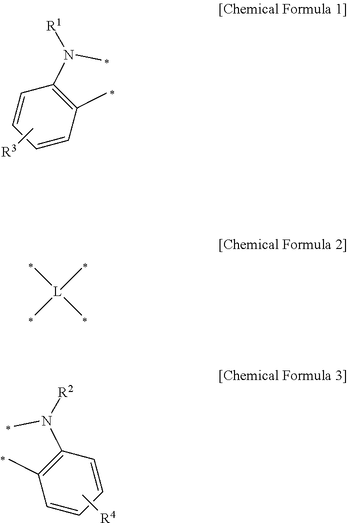

In the above Chemical Formulas 1 to 3,

L may be a C2 or C3 alkenylene or a C6 to C12 arylene,

R¹ and R² may be the same or different, and may each independently be an amine group, a carbazolyl group, a C1 to C30 alkyl group, a C6 to C30 aryl group, or a combination thereof, and

R³ and R⁴ may be the same or different, and may each independently be hydrogen, an amine group, a carbazolyl group, a C1 to C30 alkyl group, a C6 to C30 aryl group, or a combination thereof.

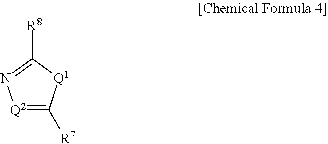

In the above Chemical Formula 4,

Q¹ may be O or NR⁵, wherein R⁵ may be a C1 to C60 alkyl group, a C6 to C60 aryl group, or a combination thereof,

Q² may be N or CR⁶, wherein R⁶ may be a C1 to C60 alkyl group, a C1 to C60 alkylene group, a C2 to C60 alkenyl group, a C2 to C60 alkenylene group, a C6 to C60 aryl group, a C6 to C60 arylene group, or a combination thereof, or R⁶ may be linked to R⁷ to form a fused ring,

R⁷ may be an amine group, a carbazolyl group, a fluorenyl group, a fluorenylene group, a C1 to C60 alkyl group, a C1 to C60 alkylene group, a C2 to C60 alkenyl group, a C2 to C60 alkenylene group, a C6 to C60 aryl group, a C6 to C60 arylene group, a C3 to C60 heteroaryl group, a C3 to C60 heteroarylene group, or a combination thereof, and

R⁸ may be an amine group, a carbazolyl group, a fluorenyl group, a C1 to C60 alkyl group, a C6 to C60 aryl group, or a combination thereof.

The substituent represented by the above Chemical Formula 2 may be represented by one or more of the following Chemical Formulas 2a to 2c:

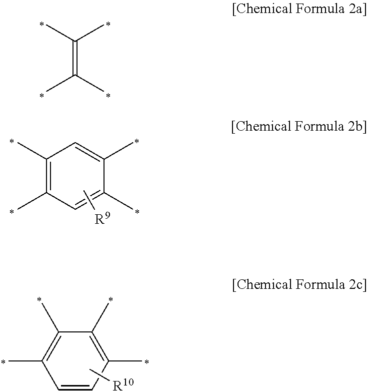

In the above Chemical Formulas 2a to 2c, R⁹ and R¹⁰ may be the same or different, and may each independently be hydrogen, an amine group, a carbazolyl group, a C1 to C30 alkyl group, a C6 to C30 aryl group, or a combination thereof.

The first host compound may be represented by one or more of the following Chemical Formulas 6 to 12:

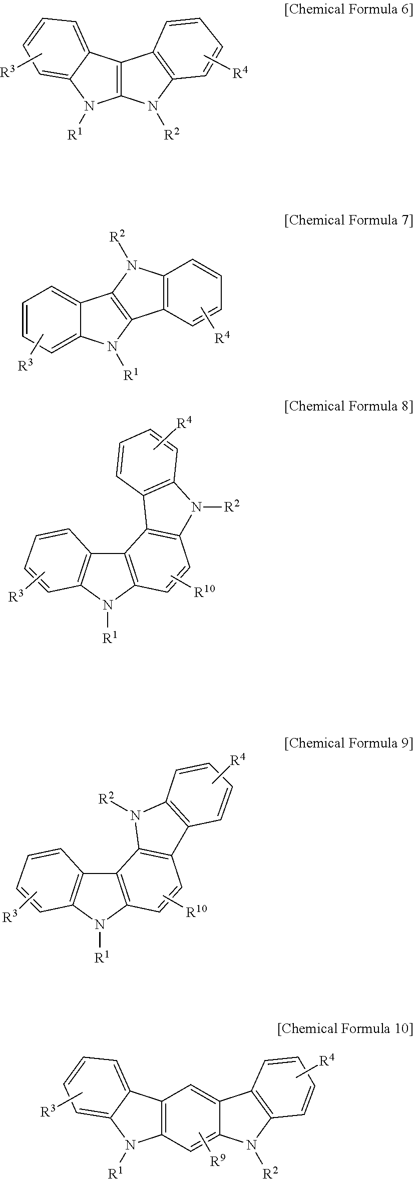

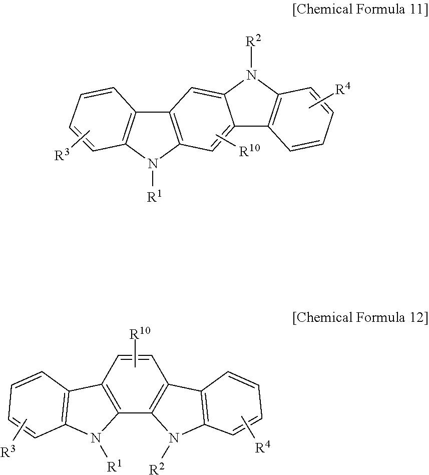

In the above Chemical Formulas 6 to 12,

R¹ and R² may be the same or different, and may each independently be an amine group, a carbazolyl group, a C1 to C30 alkyl group, a C6 to C30 aryl group, or a combination thereof, and

R³, R⁴, R⁹ and R¹⁰ may be the same or different, and may each independently be hydrogen, an amine group, a carbazolyl group, a C1 to C30 alkyl group, a C6 to C30 aryl group, or a combination thereof.

The first host compound may be represented by one or more of the following Chemical Formulas 13 to 42.

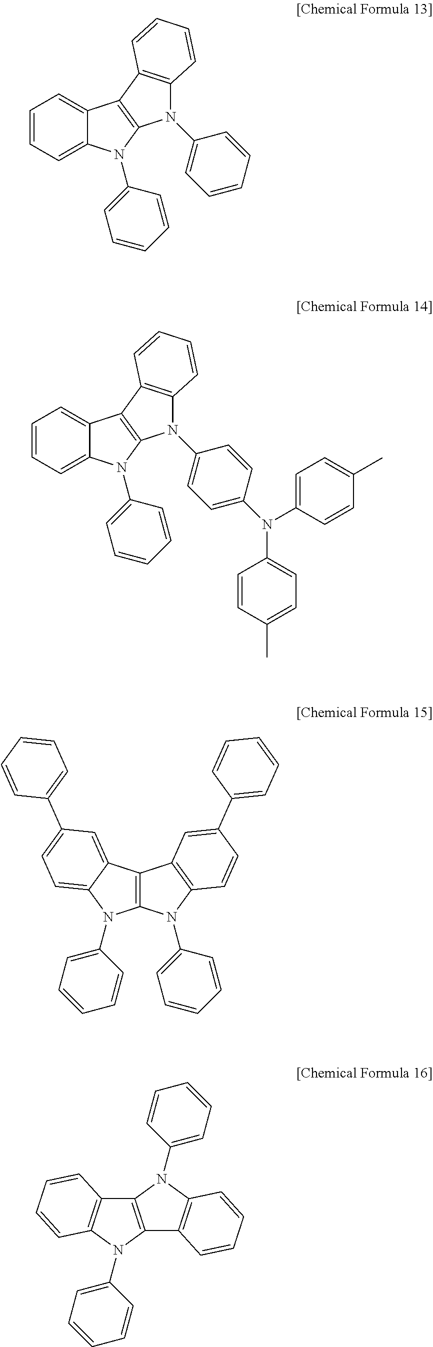

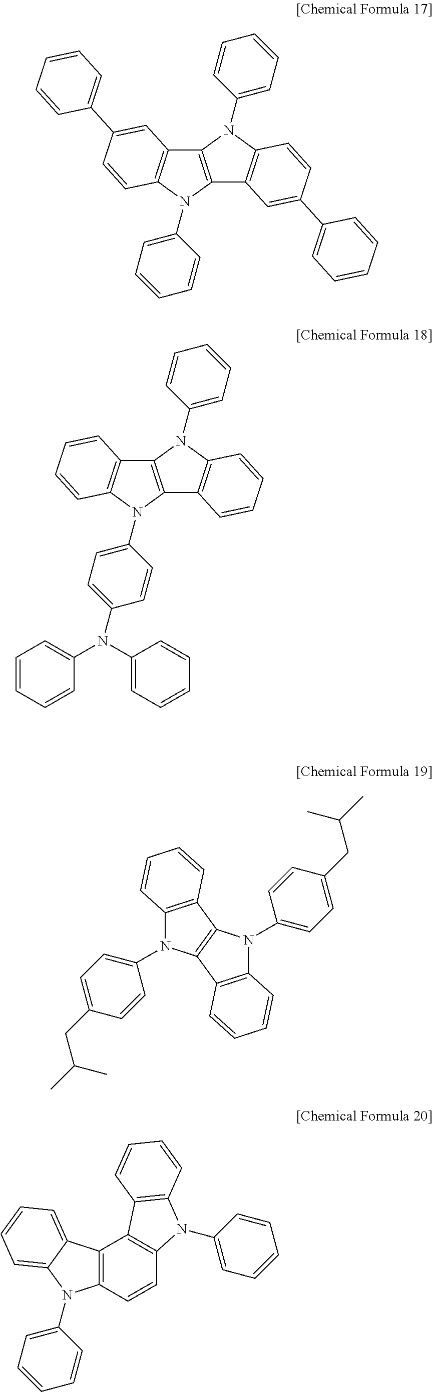

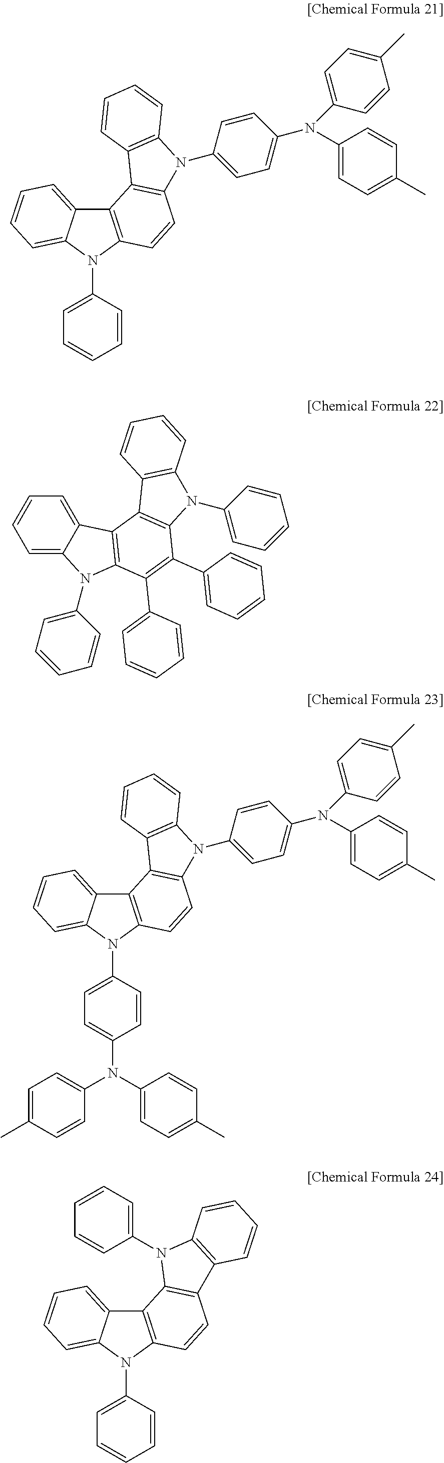

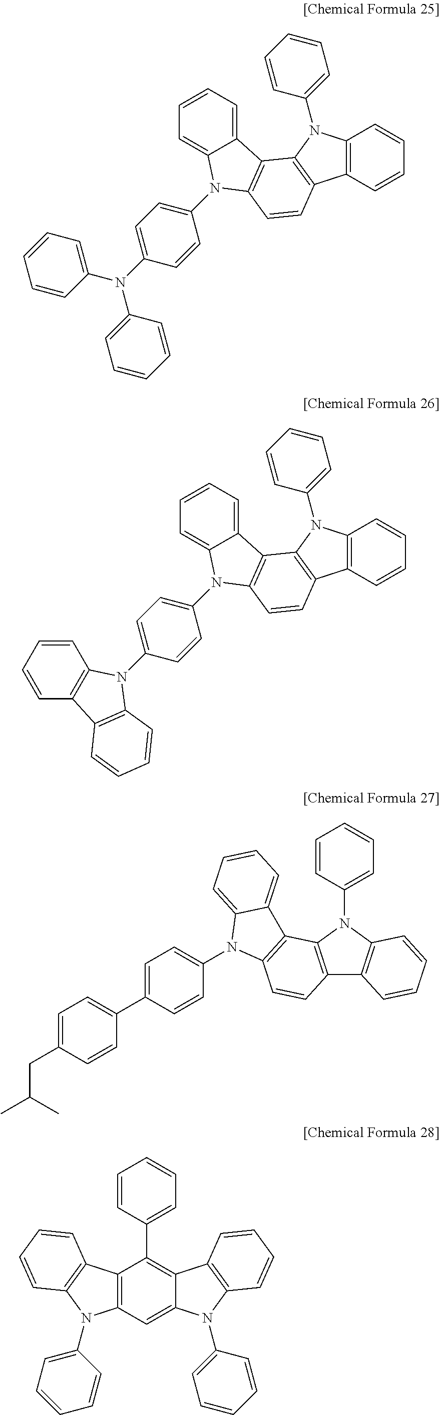

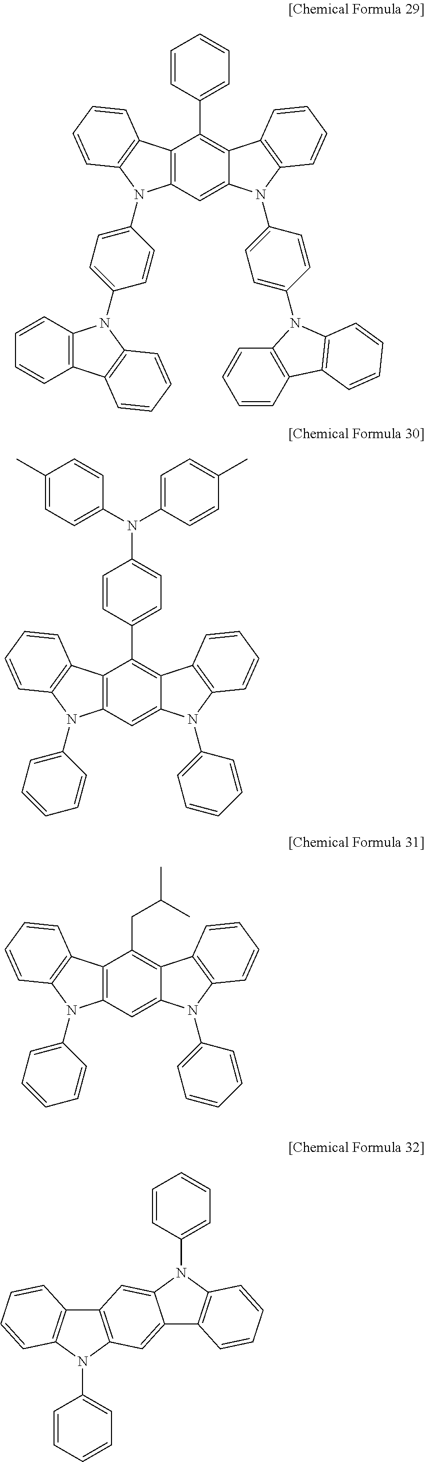

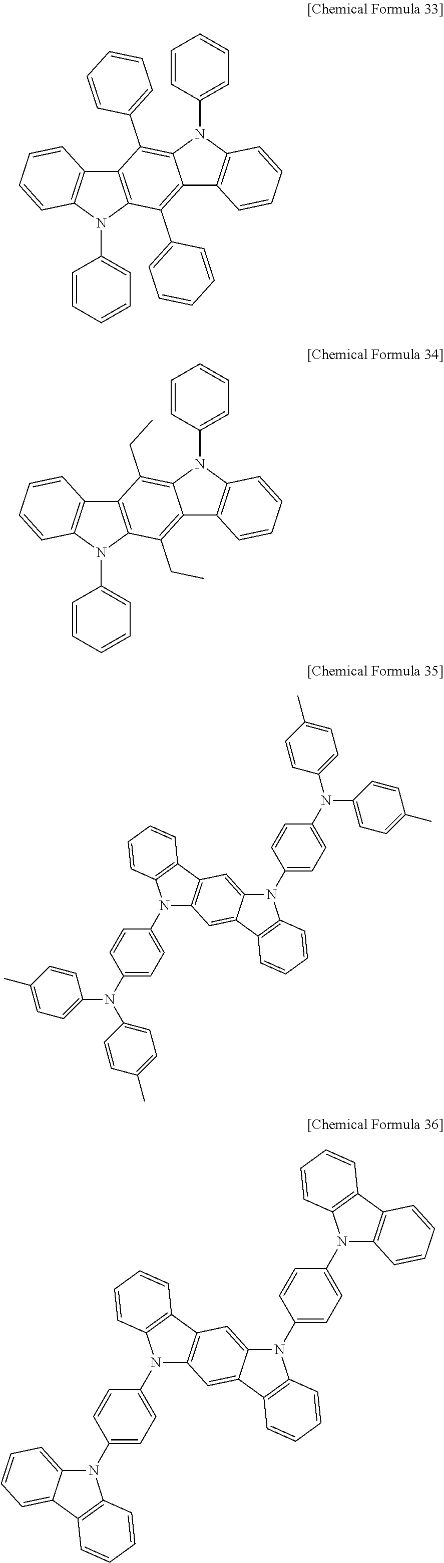

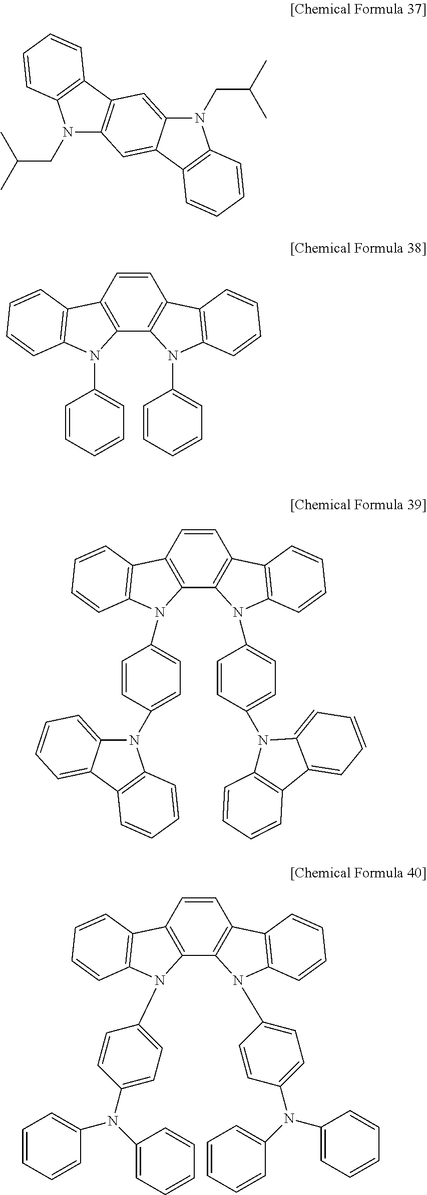

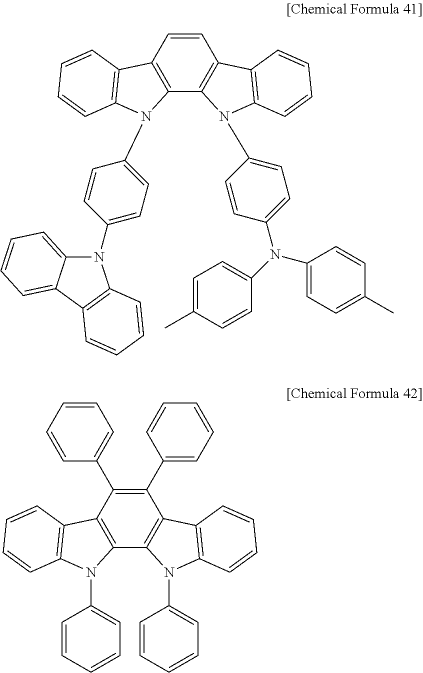

The second host compound represented by the above Chemical Formula 4 may be represented by one or more of the following Chemical Formulas 4a to 4b:

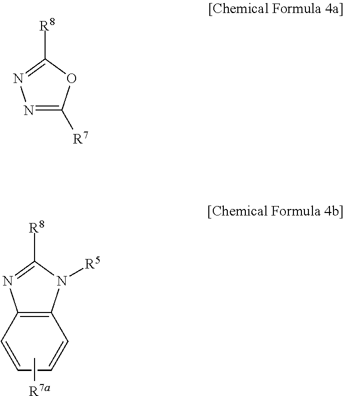

In Chemical Formulas 4a to 4b,

R⁵ may be a C1 to C60 alkyl group, a C6 to C60 aryl group, or a combination thereof,

R⁷ and R^{7a} may be the same or different, and may each independently be an amine group, a carbazolyl group, a fluorenyl group, a C1 to C60 alkyl group, a C2 to C60 alkenyl group, a C6 to C60 aryl group, a C3 to C60 heteroaryl group, or a combination thereof, and

R⁸ may be an amine group, a carbazolyl group, a fluorenyl group, a C1 to C60 alkyl group, a C6 to C60 aryl group, or a combination thereof.

The second host compound represented by the above Chemical Formula 4 may he represented by the following Chemical Formula 4c:

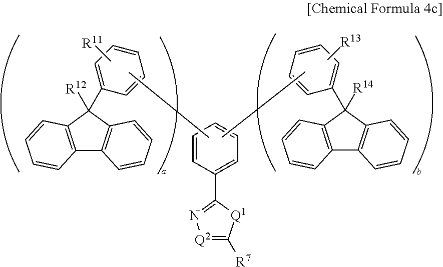

In the above Chemical Formula 4c,

Q¹ may be O or NR⁵, wherein R⁵ may be a C1 to C60 alkyl group, a C6 to C60 aryl group, or a combination thereof,

Q² may be N or CR⁶, wherein R⁶ may be a C1 to C60 alkyl group, a C1 to C60 alkylene group, a C2 to C60 alkenyl group, a C2 to C60 alkenylene group, a C6 to C60 aryl group, a C6 to C60 arylene group, or a combination thereof, or R⁶ may be linked to R⁷ to form a fused ring,

R⁷ may be an amine group, a carbazolyl group, a fluorenyl group, a fluorenylene group, a C1 to C60 alkyl group, a C1 to C60 alkylene group, a C2 to C60 alkenyl group, a C2 to C60 alkenylene group, a C6 to C60 aryl group, a C6 to C60 arylene group, a C3 to C60 heteroaryl group, a C3 to C60 heteroarylene group, or a combination thereof,

R¹¹ to R¹⁴ may be the same or different, and may each independently be a C1 to C60 alkyl group, a C1 to C60 alkylene group, a C2 to C60 alkenyl group, a C2 to C60 alkenylene group, a C6 to C60 aryl group, a C6 to C60 arylene group, or a combination thereof, or R¹¹ may be linked to R¹² to form a fused ring, or R¹³ may be linked to R¹⁴ to form a fused ring, and

a and b may be the same or different, and may each independently 0 or 1, and a+b may be an integer of greater than or equal to 1.

The second host compound may be represented by one or more of the following Chemical Formulas 43 to 46.

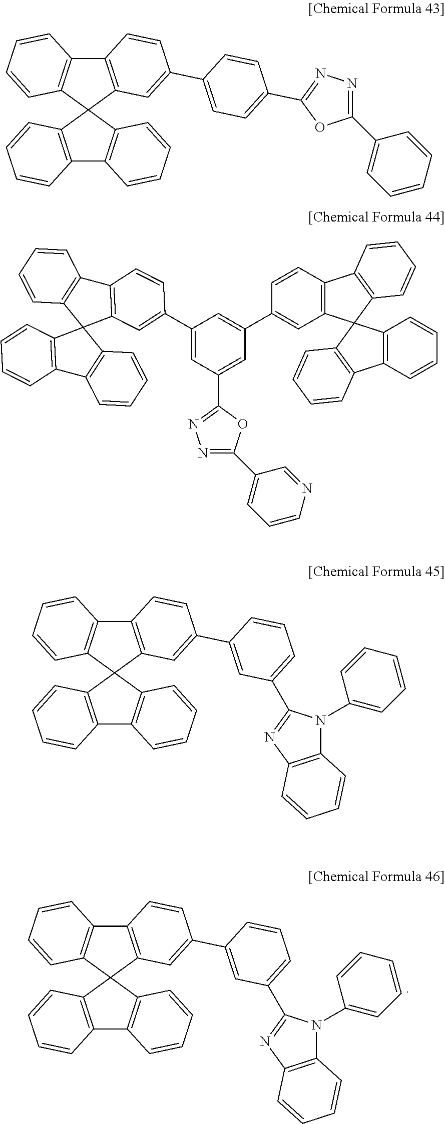

The composition may include the first host compound and the second host compound at a weight ratio of about 50:1 to about 50:2,500.

Embodiments are also directed to an organic photoelectric device, including an anode, a cathode, and an organic thin layer, the organic thin layer being between the anode and the cathode, the organic thin layer including the composition according to an embodiment.

The composition may be present as a phosphorescent host material.

The composition may be present in an emission layer.

The emission layer may further include a dopant.

The dopant may be a red, green, or blue phosphorescent dopant.

The organic thin layer may include the emission layer and include at least one other layer between the anode and the cathode, the at least one other layer being selected from the group of a hole transport layer, a hole injection layer, a hole blocking layer, an electron transport layer, an electron injection layer, an electron blocking layer, and a combination thereof.

Embodiments are also directed to a display device including the organic photoelectric device according to an embodiment.

### BRIEF DESCRIPTION OF THE DRAWINGS

Features will become apparent to those of skill in the art by describing in detail exemplary embodiments with reference to the attached drawings in which:

FIGS. 1 to 5 illustrate cross-sectional views showing organic photoelectric devices including compositions for an organic photoelectric device according to various embodiments.

FIG. 6 illustrates luminance according to a driving voltage.

FIG. 7 illustrates current efficiency according to luminance.

### DETAILED DESCRIPTION

Korean Patent Application No. 10-2009-0105574, filed on Nov. 3, 2009, in the Korean Intellectual Property Office, and entitled: “Composition for Organic Photoelectric Device, Organic Photoelectric Device Using the Same and Display Device Comprising the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Description of Reference Numerals Indicating Primary Elements in the Drawings:

| | |
|---|---|
| 100: organic photoelectric device | 110: cathode |
| 120: anode | 105: organic thin layer |
| 130: emission layer | 140: hole transport layer (HTL) |
| 150: electron transport layer (ETL) | 160: electron injection layer (EIL) |
| 170: hole injection layer (HIL) | |

230: emission layer + electron transport layer (ETL)

In the present specification, the term “hetero,” when a definition is not otherwise provided, refers to one including 1 to 3 of N, O, S, P, and remaining carbons in one ring.

The composition for an organic photoelectric device in accordance with an embodiment may have high solubility in an organic solvent. Further, when a thin film is formed of the composition through a wet process, excellent film quality may be provided, including, e.g., when the composition includes a host compound having a low molecular weight according to an embodiment.

An embodiment provides a composition for an organic photoelectric device that includes a first compound including substituents represented by the following Chemical Formulas 1 to 3 sequentially combined; and a second host compound represented by the following Chemical Formula 4.

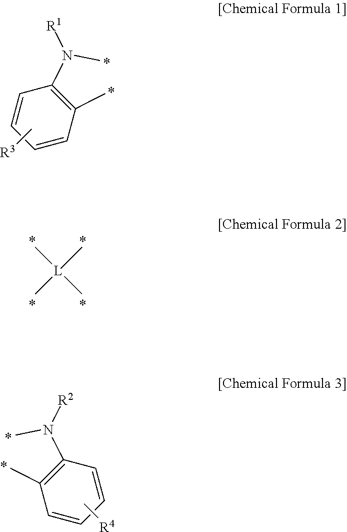

In the above Chemical Formulas 1 to 3, L may be, e.g., a C2 or C3 alkenylene or a C6 to C12 arylene. When L is the C2 or C3 alkenylene, in the above Chemical Formulas 1 and 3, each N-containing ring may be, e.g., a five-membered or six-membered ring.

In the above Chemical Formulas 1 to 3, R¹ and R² may be the same or different, and may each independently be, e.g., an amine group, a carbazolyl group, a C1 to C30 alkyl group, a C6 to C30 aryl group, or a combination thereof. In an implementation, the R¹ and R² may be, e.g., a carbazolyl group, a C3 to C30 alkyl group, a C6 to C20 aryl group, a C6 to C30 arylcarbazolyl group, a C1 to C30 alkylcarbazolyl group, a C6 to C30 arylamine group, a C₁ to C30 alkylamine group, or the like. In this case, the substituents of R¹ and R² of the first host compound may be combined at an angle of 30° or more with respect to a plane formed by each ring including N in the above Chemical Formulas 1 and 3 to form a stereoscopic structure. The stereoscopic structure may prevent the first host compound from being easily crystallized. Also, the solubility to an organic solvent may be improved.

R³ and R⁴ may be the same or different, and may each independently be, e.g., hydrogen, an amine group, a carbazolyl group, a C1 to C30 alkyl group, a C6 to C30 aryl group, or a combination thereof,

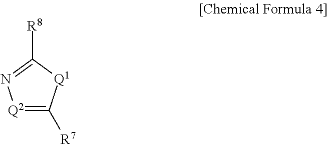

In the above Chemical Formula 4,

Q¹ may be O or NR⁵, wherein R⁵ is, e.g., a C1 to C60 alkyl group, a C6 to C60 aryl group, or a combination thereof,

Q² may be N or CR⁶, wherein R⁶ is, e.g., a C1 to C60 alkyl group, a C1 to C60 alkylene group, a C2 to C60 alkenyl group, a C2 to C60 alkenylene group, a C6 to C60 aryl group, a C6 to C60 arylene group, or a combination thereof, or R⁶ may be linked to R⁷ to form a fused ring,

R⁷ may be, e.g., an amine group, a carbazolyl group, a fluorenyl group, a fluorenylene group, a C1 to C60 alkyl group, a C1 to C60 alkylene group, a C2 to C60 alkenyl group, a C2 to C60 alkenylene group, a C6 to C60 aryl group, a C6 to C60 arylene group, a C3 to C60 heteroaryl group, a C3 to C60 heteroarylene group, or a combination thereof, and

R⁸ may be an amine group, a carbazolyl group, a fluorenyl group, a C1 to C60 alkyl group, a C6 to C60 aryl group, or a combination thereof.

Herein, the heteroaryl group and heteroarylene group may each independently include 1 to 3 heteroatoms selected from the group of N, O, S, and P, and remaining carbon. They preferably include an N atom. In an implementation, they may be groups corresponding to, e.g., pyridine, pyrimidine, triazine, and the like.

The first host compound may be a hole transport compound, and the second host compound may be an electron transport compound. The hole transport compound means a compound having a conductive characteristic according to a HOMO level and having a cation characteristic due to formation of holes. The electron transport compound means a compound having a conductive characteristic according to a LUMO level and having a negative ion characteristic due to formation of electrons.

Therefore, a composition for an organic photoelectric device in accordance with one embodiment may have a bipolar characteristic. Thus, the composition for an organic photoelectric device may show excellent interface characteristics and charge transfer capability in an emission layer of an organic photoelectric device where holes and electrons are combined.

The substituent represented by the above Chemical Formula 2 may be represented by one or more of the following Chemical Formulas 2a to 2c.

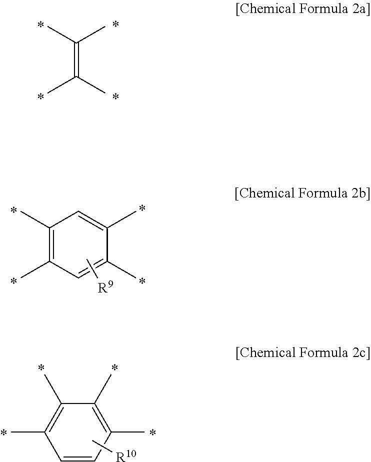

In the above Chemical Formulas 2a to 2c, R⁹ and R¹⁰ may be the same or different, and may each independently be, e.g., hydrogen, an amine group, a carbazolyl group, a C1 to C30 alkyl group, a C6 to C30 aryl group, or a combination thereof.

The first host compound may be represented by one or more of the following Chemical Formulas 6 to 12.

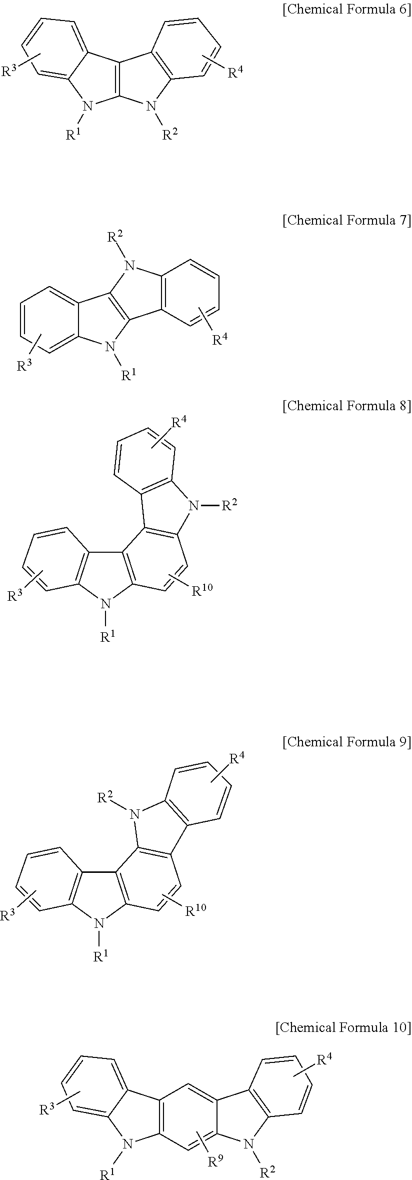

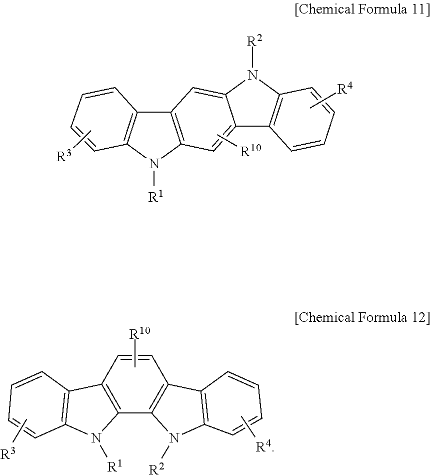

In the above Chemical Formulas 6 to 12,

R¹ and R² may be the same or different, and may each independently be, e.g., an amine group, a carbazolyl group, a C1 to C30 alkyl group, a C6 to C30 aryl group, or a combination thereof, and

R³, R⁴, R⁹ and R¹⁰ may be the same or different, and may each independently be, e.g., hydrogen, an amine group, a carbazolyl group, a C1 to C30 alkyl group, a C6 to C30 aryl group, or a combination thereof.

In an implementation, the first host compound may be represented by one or more of the following Chemical Formulas 13 to 42.

The second host compound represented by the above Chemical Formula 4 may be represented by one or more of the following Chemical Formula 4a to Chemical Formula 4b.

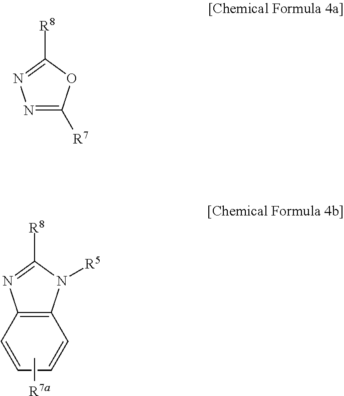

In the above Chemical Formulas 4a to 4b,

R⁵ may be, e.g., a C1 to C60 alkyl group, a C6 to C60 aryl group, or a combination thereof,

R⁷ and R^{7a} may be the same or different, and may each independently be, e.g., an amine group, a carbazolyl group, a fluorenyl group, a C1 to C60 alkyl group, a C2 to C60 alkenyl group, a C6 to C60 aryl group, a C3 to C60 heteroaryl group, or a combination thereof, and

R⁸ may be an amine group, a carbazolyl group, a fluorenyl group, a C1 to C60 alkyl group, a C6 to C60 aryl group, or a combination thereof.

The second host compound represented by the above Chemical Formula 4 may be represented by the following Chemical Formula 4c.

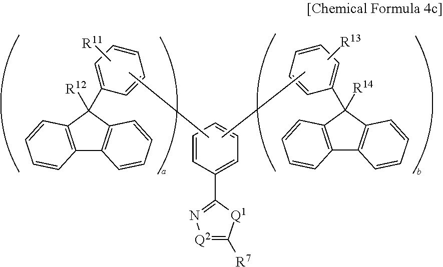

In the above Chemical Formula 4c,

Q¹ may be O or NR⁵, wherein R⁵ may be, e.g., a C1 to C60 alkyl group, a C6 to C60 aryl group, or a combination thereof,

Q² may be N or CR⁶, wherein R⁶ may be, e.g., a C1 to C60 alkyl group, a C1 to C60 alkylene group, a C2 to C60 alkenyl group, a C2 to C60 alkenylene group, a C6 to C60 aryl group, a C6 to C60 arylene group, or a combination thereof, or R⁶ may be linked to R⁷ to form a fused ring,

R⁷ may be, e.g., an amine group, a carbazolyl group, a fluorenyl group, a fluorenylene group, a C1 to C60 alkyl group, a C1 to C60 alkylene group, a C2 to C60 alkenyl group, a C2 to C60 alkenylene group, a C6 to C60 aryl group, a C6 to C60 arylene group, a C3 to C60 heteroaryl group, a C3 to C60 heteroarylene group, or a combination thereof,

R¹¹ to R¹⁴ may be the same or different, and may each independently be, e.g., a C1 to C60 alkyl group, a C1 to C60 alkylene group, a C2 to C60 alkenyl group, a C2 to C60 alkenylene group, a C6 to C60 aryl group, a C6 to C60 arylene group, or a combination thereof, or R¹¹ may be linked to R¹² to form a fused ring, or R¹³ may be linked to R¹⁴ to form a fused ring, and

a and b may be natural numbers that are the same or different. In an implementation, a and b and are each independently 0 or 1. In an implementation, at least one of the groups corresponding to a and b is present. In an implementation, a+b is an integer of greater than or equal to 1.

The second host compound may be presented by one or more of the following Chemical Formulas 43 to 46.

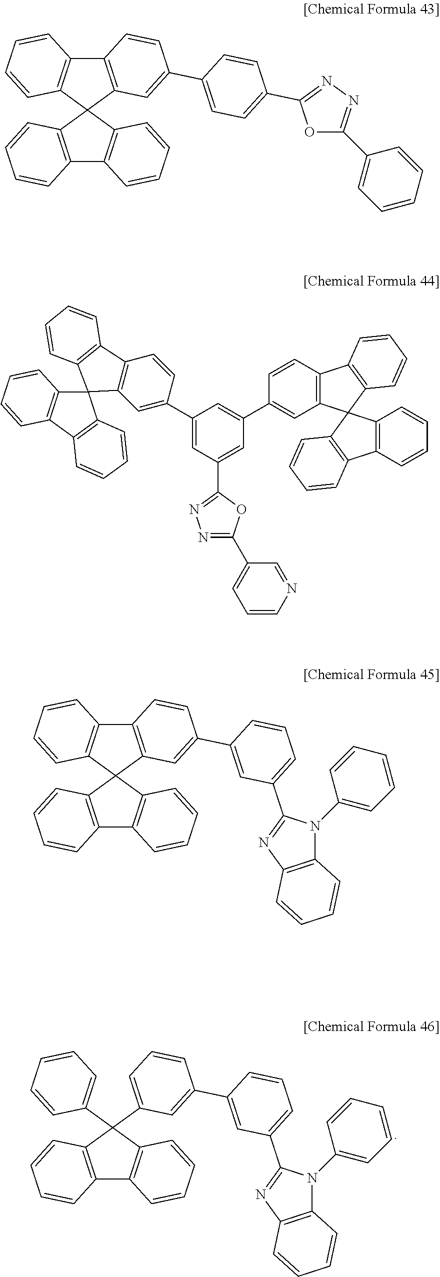

The composition for an organic photoelectric device according to an embodiment may include the first host compound and the second host compound at a weight ratio of about 50:1 to about 50:2,500. (about 50 first host compound:1 second host compound to about 50 first host compound:2,500 second host compound).

The composition for an organic photoelectric device according to an embodiment may be suitably applicable to a thin layer formation with a wet process using an organic solvent. The organic solvent may be a generally-used solvent. For example, the organic solvent may include an aromatic organic solvent such as toluene, xylene, or the like; a halogen-substituted aromatic organic solvent such as chlorobenzene, dichlorobenzene, or the like; a polar organic solvent such as pyridine, dimethylsulfoxide, dimethyl formamide, N-methylpyrrolidone, cyclohexanone, or the like; or a mixed solvent thereof.

The solvent may be used in an amount of, e.g., about 100 to about 20,000 parts by weight based on 100 parts by weight of the first host compound and the second host compound. In the solvent, when the sum of the first host compound and the second host compound is greater than or equal to 0.5 wt %, the composition may be applicable to an organic photoelectric device, and particularly, greater than or equal to 1.5 wt %.

Another embodiment may provide an organic photoelectric device that includes an anode, a cathode, and an organic thin layer between the anode and the cathode. The organic thin layer may include the composition for an organic photoelectric device according to an embodiment. Examples of the organic optoelectronic device according to embodiments may include an organic light emitting diode, an organic solar cell, an organic transistor, an organic photo-conductor drum, an organic memory device, and the like. In an implementation, the composition for an organic photoelectric device according to an embodiment may be included in an electrode or an electrode buffer layer in the organic solar cell to improve quantum efficiency. In an implementation, the composition for an organic photoelectric device according to an embodiment may be used as an electrode material for a gate, a source-drain electrode, or the like in the organic transistor.

The organic thin layer may include one or more of an emission layer, a hole transport layer (HTL), a hole injection layer (HIL), a hole blocking layer, an electron transport layer (ETL), an electron injection layer (EIL), an electron blocking layer. The emission layer may include the composition for an organic photoelectric device according to an embodiment. The composition for an organic photoelectric device may be used as a phosphorescent host material. The organic thin layer may further include a dopant, and the dopant may be a red, green, or blue phosphorescent dopant.

The dopant may be a compound having a high emission property, by itself. Added to a host in a minor amount, it may be referred to as a guest or a dopant. The dopant is a material that is doped to the host material to emit light. In an implementation, the dopant may include a metal complex that emits light due to multiplet excitation into a triplet or higher state. The dopant may be a generally-used fluorescent or phosphorescent dopant of red (R), green (G), and blue (B) colors. Red, green, or blue phosphorescent dopant may be preferable. The dopant may have a high luminous efficiency, may be resistant to agglomeration, and may be distributed uniformly in the host material.

The phosphorescent dopant may be an organic metal compound including at least one element of Ir, Pt, Os, Ti, Zr, Hf, Eu, Tb, Tm, Fe, Co, Ni, Ru, Rh, Pd, or combinations thereof. The phosphorescent dopant may be represented by, e.g., the following Chemical Formulas 51 to 53.

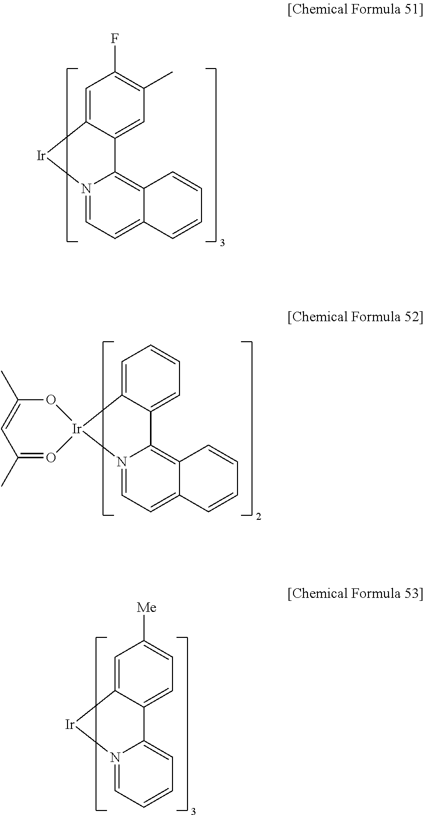

Hereinafter, an organic photoelectric device according to an embodiment is described in detail.

FIGS. 1 to 5 illustrate cross-sectional views showing organic photoelectric devices including the organic compounds according to an embodiment.

Referring to FIGS. 1 to 5, organic photoelectric devices 100, 200, 300, 400, and 500 may include at least one organic thin layer 105 interposed between an anode 120 a cathode 110.

A substrate of the organic photoelectric device may be a generally-used substrate. In an implementation, a glass substrate, or a transparent plastic substrate having excellent general transparence, face smoothness, handling ease, and water repellency may be used.

The anode 120 may include an anode material laving a large work function to help hole injection into the organic thin layer. The anode may include a metal such as nickel, platinum, vanadium, chromium, copper, zinc, gold, or alloys thereof; a metal oxide such as zinc oxide, indium oxide, indium tin oxide (ITO), or indium zinc oxide (IZO); a combined metal and oxide such as ZnO/Al or SnO₂/Sb; or a conductive polymer such as poly(3-methylthiophene), poly[3,4-(ethylene-1,2-dioxy)thiophene] (PEDOT or PEDT), PEDOT/polystyrenesulfonate(polystyrenesulfonate: PSS), polypyrrole, or polyaniline. A transparent electrode including ITO as the anode is preferable.

The cathode 110 may include a material having a small work function to help electron injection into an organic thin layer. The cathode material may include a metal such as magnesium, calcium, sodium, potassium, titanium, indium, yttrium, lithium, gadolinium, aluminum, silver, tin, lead, cesium, barium, or the like, or alloys thereof; or a multi-layered material such as LiF/Al, LiO₂/Al, LiF/Ca, LiF/Al, BaF₂/Ca, or the like. A metal electrode including aluminum is preferable as the cathode.

In the example embodiment shown in FIG. 1, the organic light emitting diode 100 includes the organic thin layer 105 including only an emission layer 130.

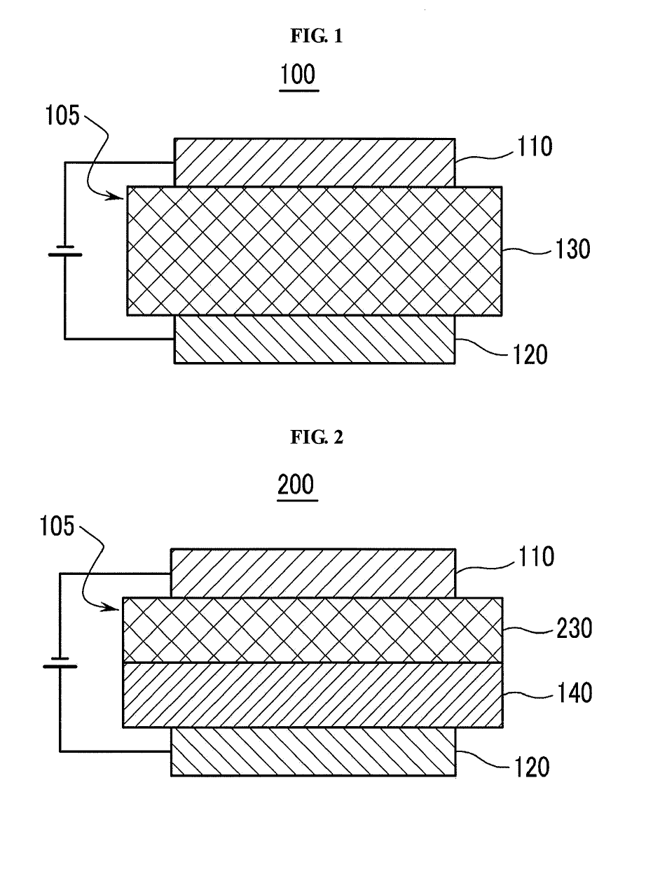

In the example embodiment shown in FIG. 2, a double-layered organic light emitting diode 200 includes the organic thin layer 105 including an emission layer 230, and a hole transport layer (HTL) 140. In an implementation, the emission layer 230 also functions as an electron transport layer (ETL).

The hole transport layer (HTL) 140 layer may have an excellent binding property with a transparent electrode such as ITO while providing a hole transporting property. The hole transport layer (HTL) 140 may include a generally-used material, e.g., poly(3,4-ethylenedioxy-thiophene) (PEDOT) doped with poly(styrenesulfonate) (PSS) (PEDOT:PSS),
N,N′-bis(3-methylphenyl)-N,N-diphenyl-(1,1′-biphenyl)-4,4′-diamine (TPD),
N,N′-di(1-naphthyl)-N,N′-diphenylbenzidine (NPB), etc.

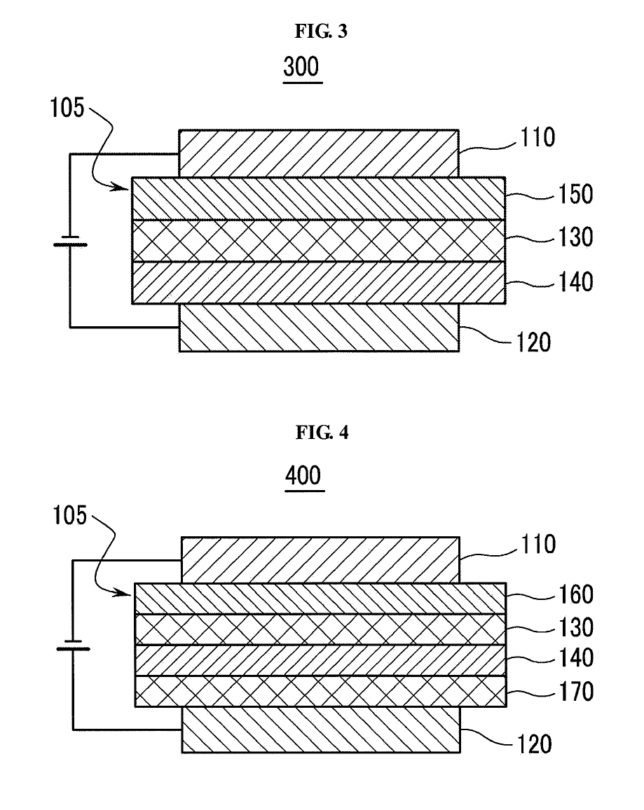

In the example embodiment shown in FIG. 3, a three-layered organic light emitting diode 300 includes the organic thin layer 105, which includes an electron transport layer (ETL) 150, the emission layer 130, and the hole transport layer (HTL) 140. The emission layer 130 may be an independent layer, and layers having an excellent electron transporting property and an excellent hole transporting property may be respectively separately stacked therewith.

The electron transport layer (ETL) 150 may include a generally-used material, e.g., aluminum tris(8-hydroxyquinoline) (Alq₃); a 1,3,4-oxadiazole derivative such as 2-(4-biphenyl)-5-phenyl-1,3,4-oxadiazole (PBD); a quinoxaline derivative such as 1,3,5-tris[(3-phenyl-6-trifluoromethyl)quinoxalin-2-yl]benzene (TPQ); or a triazole derivative, etc.

In the example embodiment shown in FIG. 4, a four-layered organic light emitting diode 400 includes the organic thin layer 105, which includes an electron injection layer (EIL) 160, the emission layer 130, the hole transport layer (HTL) 140, and a hole injection layer (HIL) 170 for binding with the cathode of ITO.

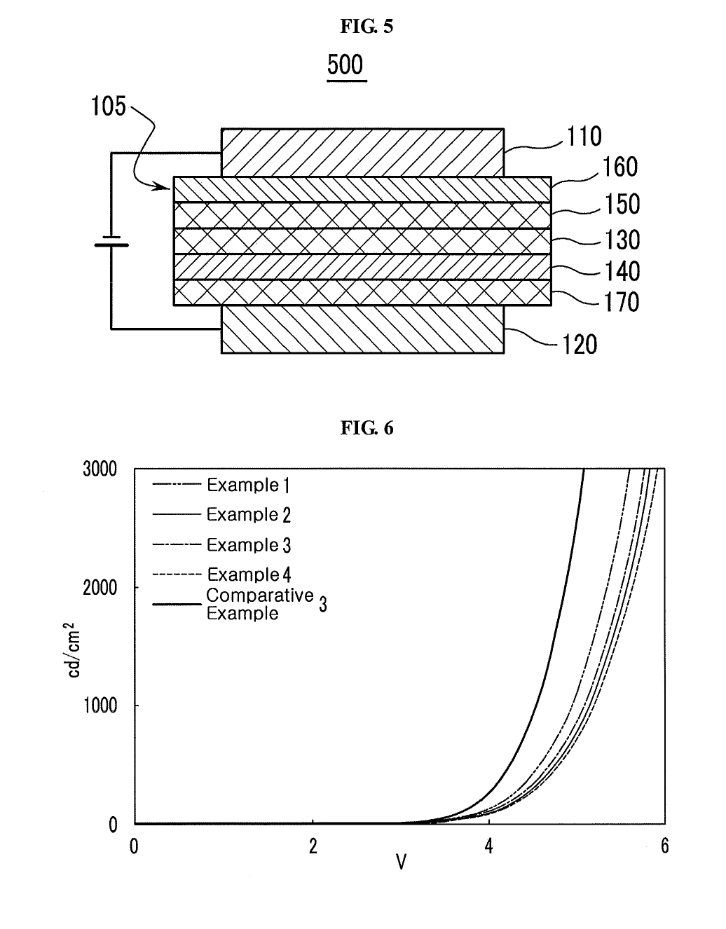

In the example embodiment shown in FIG. 5, a five layered organic light emitting diode 500 includes the organic thin layer 105, which includes the electron transport layer (ETL) 150, the emission layer 130, the hole transport layer (HTL) 140, and the hole injection layer (HIL) 170, and further includes an electron injection layer (EIL) 160 to achieve a low voltage.

The hole transport layer (HTL) 140 and electron transport layer (ETL) 150 may have a thickness of, e.g., about 10 to about 10,000 Å, respectively.

In FIGS. 1 to 5, the emission layers 130 and 230 as the organic thin layer 105 may be formed using the composition for an organic photoelectric device according to an embodiment.

The organic photoelectric device may be fabricated by, e.g.: forming an anode on a substrate; forming an organic thin layer in accordance with a dry process such as evaporation, sputtering, plasma plating, or ion plating, or a wet process such as inkjet printing, screen printing, slit coating, spin coating, dipping, or flow coating; and providing a cathode thereon. In an implementation, the organic thin layer may be formed using a wet process.

Another embodiment may provide a display device including the organic photoelectric device according to an embodiment.

The following Examples and Comparative Examples are provided in order to set forth particular details of one or more embodiments. However, it will be understood that the embodiments are not limited to the particular details described. Further, the Comparative Examples are set forth to highlight certain characteristics of certain embodiments, and are not to he construed as either limiting the scope of the invention as exemplified in the Examples or as necessarily being outside the scope of the invention in every respect.

### PREPARATION EXAMPLE 1

### Synthesis of Compound of Chemical Formula 20

The compound of Chemical Formula 20 was synthesized according to the following method of Reaction Scheme 1.

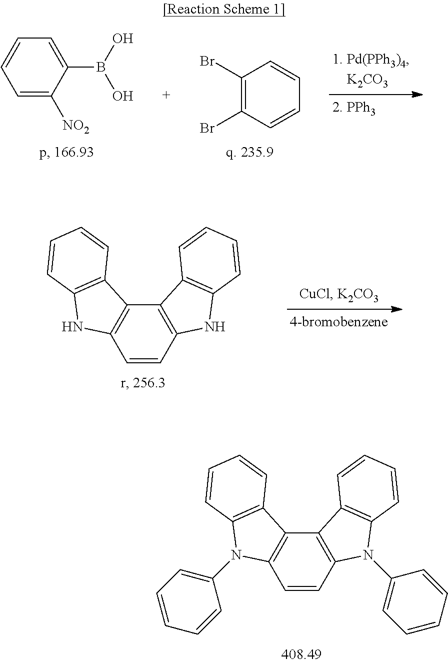

Referring to Reaction Scheme 1, 3.6 g of compound p, 2.3 g of compound q, 0.5 g of Pd(PPh₃)₄, and 5 g of K₂CO₃ were mixed in 50 mL of toluene, and agitated at 100° C. for 24 hours, and quenched to room temperature. Subsequently, 50 mL of distilled water was added, and the mixture was agitated for 10 minutes and separated into an aqueous solution layer and an organic layer, and then the aqueous solution layer was removed. The organic layer was concentrated under reduced pressure, and then 1.5 g of product was separated through a silica gel column chromatography using a mixed solvent of chloroform:hexane (1:1 volume ratio) as an eluent. 1.5 g of the separated product and 5 g of triphenylphosphine (PPh₃) were mixed with 20 mL of dichlorobenzene and agitated at 150° C. for 12 hours, and then quenched to room temperature. Subsequently, 50 mL of distilled water was added, and agitated for 10 minutes and separated into an aqueous solution layer and an organic layer, and the aqueous solution layer was removed. The organic layer was concentrated under reduced pressure, and 0.8 g of compound r was separated through a silica gel column chromatography using a mixed solvent of chloroform:hexane (1:3 volume ratio) as an eluent.

Then, 0.8 g of the compound r, 1.5 g of 4-bromobenzene, 0.1 g of CuCl and 2 g of K₂CO₃ were mixed with 10 mL of dimethylsulfoxide and agitated at 170° C. for 12 hours, and quenched to room temperature. Subsequently, 30 mL of dichloromethane and 30 mL of distilled water were added and agitated for 10 minutes, and separated into an aqueous solution layer and an organic layer, and the aqueous solution layer was removed. The organic layer was concentrated under reduced pressure, and 0.8 g of the compound of Chemical Formula 20 was obtained through a silica gel column chromatography using a mixed solvent of chloroform:hexane (1:4 volume ratio) as an eluent.

The synthesized compound was analyzed with mass spectroscopy, and the analysis result was as follows.

MS(ESI) m/z 409.15(M+H)⁺

### PREPARATION EXAMPLE 2

### Synthesis of Compound of Chemical Formula 28

The compound of Chemical Formula 38 was synthesized according to the following method of Reaction Scheme 2.

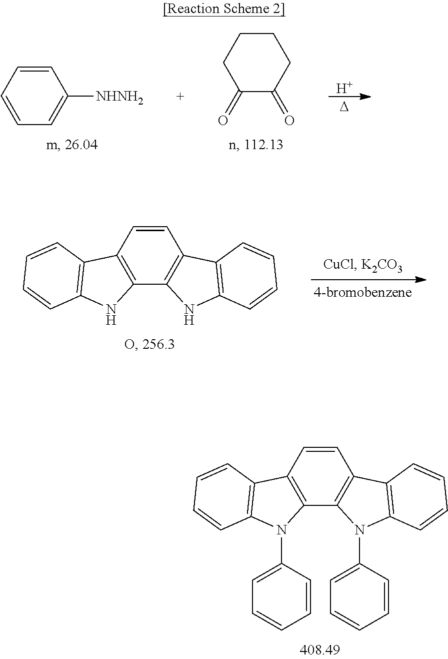

Referring to Reaction Scheme 2, 45 g of compound m, 16 g of compound n, and 1 g were mixed with 500 mL of ethanol, and agitated at 65° C. for 12 hours, and quenched to room temperature. Crystals formed during the process were filtered and dried so as to obtain an intermediate product, and the intermediate product was mixed with 35 g of trifluoroacetic acid and 500 mL of acetic acid. The mixture was agitated at 100° C. for 24 hours and quenched to room temperature to obtain yellow crystals. The crystals were purified, cleaned three times with 200 mL of hexane, and dried to obtain 16 g of compound o.

Then, 2.5 g of the compound o, 4.0 g of 4-bromobenzene, 0.1 g of CuCl, and 10 g of K₂CO₃ were mixed with 30 mL of dimethylsulfoxide and agitated at 170° C. for 12 hours, and quenched to room temperature. Subsequently, 30 mL of dichloromethane and 30 mL of distilled water were added and agitated for 10 minutes, and separated into an aqueous solution layer and an organic layer, and the aqueous solution layer was removed. The organic layer was concentrated under reduced pressure, and 2.0 g of the compound of Chemical Formula 38 was obtained through a silica gel column chromatography using a mixed solvent of chloroform:hexane (1:4 volume ratio) as an eluent.

The synthesized compound was analyzed with mass spectroscopy, and the analysis result was as follows.

MS(ESI) m/z 409.15(M+H)⁺

### PREPARATION EXAMPLE 3

### Synthesis of Compound of Chemical Formula 43

The compound of Chemical Formula 43 was synthesized according to the following method of Reaction Scheme 3.

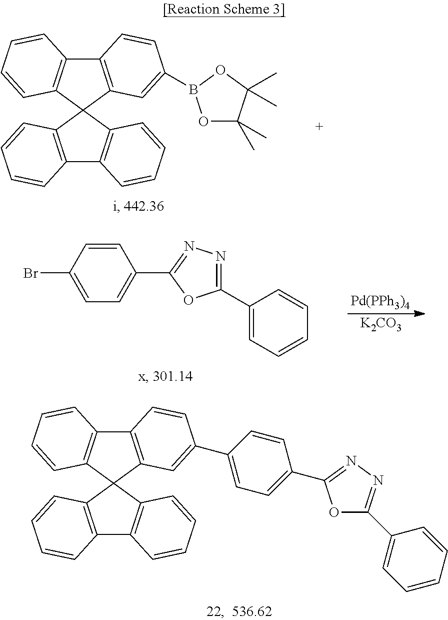

Referring to Reaction Scheme 3, 5 g of compound i and 4 g of compound x were mixed with a mixture of 100 mL of tetrahydrofuran and 80 mL of 2M potassium carbonate in a 250 mL round-bottomed flask with a reflux condenser and an agitator attached thereto. 0.23 g of Pd(PPh₃)₄ was added to the mixture and refluxed.

A resultant after the reaction was extracted using methylene chloride, and the solvent was removed by removing moisture with anhydrous magnesium sulfate. The resultant was purified through a silica gel column chromatography so as to obtain 3 g of the compound of Chemical Formula 43.

### PREPARATION EXAMPLE 4

### Synthesis of Compound of Chemical Formula 44

The compound of Chemical Formula 44 was synthesized according to the following method of Reaction Scheme 4.

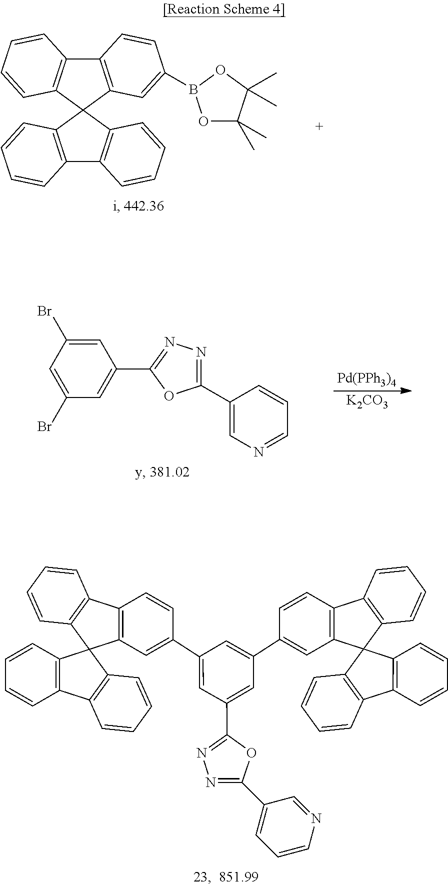

Referring to Reaction Scheme 4, 5 g of compound i and 2 g of compound y were mixed with 100 mL of tetrahydrofuran and 80 mL of 2M potassium carbonate in a 250 mL round-bottomed flask with a reflux condenser and an agitator attached thereto, and 0.23 g of Pd(PPh₃)₄ was added to the mixture and reflowed.

A resultant after the reaction was extracted using methylene chloride, and the solvent was removed by removing moisture with anhydrous magnesium sulfate. The resultant was purified through a silica gel column chromatography to obtain 3 g of the compound of Chemical Formula 44.

### EXPERIMENTAL EXAMPLE 1

### Evaluation of Solubility and Film-Forming Properties

An organic solvent was added to 30 mg of each compound, and mixed until the total weight of each solution became 1.0 g. The mixture was rolled at room temperature for 1 hour, and then filtered with a syringe filter (Acrodisc Company) whose average pore diameter was 0.2 μm. Herein, solubility and film-forming properties were compared based on CBP, which is a generally-used host compound.

(1) Solubility Evaluation Method: solubility was determined by removing the filtered solution of the solvent and measuring the mass of the remaining solid, and the result is shown in the following Table 1. Herein, chlorobenzene was selected as the organic solvent for the evaluation.

(2) Evaluation of film-forming properties: a glass substrate was spin-coated with the filtered solution. Sensory evaluation was performed on the film-forming properties of the coating layer. Herein, when the layer was transparent and smooth, it is marked with ∘; when the layer was transparent but not uniform or some fine crystals appeared, it is marked with □; and when the layer was opaque, it is marked with X. The results are shown in the following Table 1.

TABLE 1

| | Solubility | | Film-forming |
|---|---|---|---|
| Compound | Chlorobenzene | Toluene | properties |
| Chem. Form. 20 | greater than or | greater than or | ◯ |
| | equal to 3 wt % | equal to 3 wt % | |
| Chem. Form. 38 | greater than or | greater than or | ◯ |
| | equal to 3 wt % | equal to 3 wt % | |
| Chem. Form. 43 | greater than or | greater than or | ◯ |
| | equal to 3 wt % | equal to 3 wt % | |
| Chem. Form. 44 | greater than or | greater than or | ◯ |
| | equal to 3 wt % | equal to 3 wt % | |
| CBP | 1 wt % | less than or | X |
| | | equal to 0.5 wt % | |

It may be seen from Table 1 that more than 3 wt % of the compounds synthesized according to Preparation Examples 1 to 4 were all dissolved in chlorobenzene or toluene.

On the other hand, little CBP was dissolved in toluene and part of the CBP was dissolved in chlorobenzene. However, the coating layer was opaque.

### EXAMPLES 1 TO 4

### Fabrication of Organic Light Emitting Diode

First Step: Preparation of Composition for an Organic Photoelectric Device

The host compounds synthesized according to Preparation Examples 1 to 4 were mixed in the composition and weight ratio shown in the following Table 2 and used as a host. Also, the compound represented by the above Chemical Formula 49 was used as a dopant.

A composition for an organic photoelectric device was prepared by dissolving 3 wt % of the host compound in a toluene solvent, dissolving 0.5 wt % of the dopant in a chlorobenzene solvent, and mixing the two kinds of solutions.

Second Step: Fabrication of Organic Light Emitting Diode

An organic light emitting diode was manufactured in a structure of ITO/PEDOT:PSS (40 nm)/EML (host compound (87 wt %)+dopant compound (13 wt %), 50 nm)/BAlq (5 nm)/Alq₃ (20 nm)/LiF (1 nm)/Al (100 nm).

A PEDOT:PSS layer having a thickness of 40 nm was formed using an ITO substrate as an anode, spin-coating the upper part of the substrate with a PEDOT:PSS aqueous solution, and drying it at 200° C. for 10 minutes.

The upper part of the PEDOT:PSS was spin-coated with the composition for an organic photoelectric device prepared in the first step and then dried at 110° C. for 10 minutes to form an emission layer. Herein, the emission layer was formed to have a thickness of 50 nm.

A hole blocking layer having a thickness of 50 Å was formed by vacuum-depositing BAlq in the upper part of the emission layer. Also, an electron transport layer (ETL) having a thickness of 200 Å was formed by vacuum-depositing Alq₃ in the upper part of the hole blocking layer.

An organic light emitting diode was manufactured by sequentially vacuum-depositing LiF 10 Å (1 nm) and Al 1000 Å in the upper part of the electron transport layer (ETL) to form a cathode.

### COMPARATIVE EXAMPLES 1 AND 2

An organic light emitting diode was manufactured according to the same method as Example 1, except that the host compound synthesized according to Preparation Example 1 or 2 was used alone, instead of mixing and using the host compounds synthesized according to Preparation Examples 1 to 4.

### COMPARATIVE EXAMPLE 3

An organic light emitting diode was manufactured according to the same method as Example 1, except that a polyvinylcarbazole (PVK) polymer including a repeating unit represented by the following Chemical Formula 50 (which has a hole transport property) and a compound represented by the following Chemical Formula 51 (which is butyl-2-(4-biphenyl)-5-(4-tert-butylphenyl-1,3,4-oxadiazole) (PBD) and has an electron transport property) were mixed and used at a weight ratio of 1:1, instead of mixing and using the host compounds synthesized according to Preparation Examples 1 to 4.

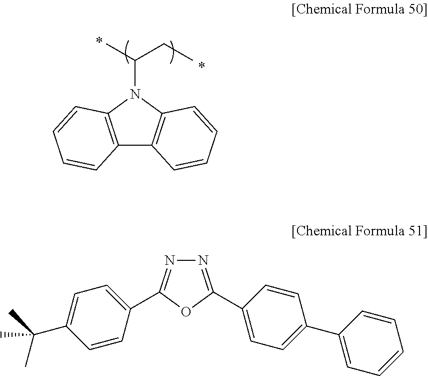

### EXPERIMENTAL EXAMPLE 2

### Performance Evaluation of Organic Light Emitting Diode

Each organic light emitting diode according to Examples 1 to 4 and Comparative Examples 1 to 5 was measured regarding current density change, luminance change, and luminous efficiency depending on a voltage. The specific measuring method is described below, and the measurement result is shown in the following Table 2.

(1) Current Density Change Depending on Voltage Change

The organic light emitting diodes were measured regarding current by increasing a voltage from 0 V to 10 V with a current-voltage meter (Keithley 2400). The current was divided by area.

(2) Luminance Change Depending on Voltage Change

The organic light emitting diodes were measured regarding luminance by increasing a voltage from 0 V to 10 V with a luminance meter (Minolta Cs-1000A). The results are shown in the following Table 2 and FIG. 6.

(3) Luminous Efficiency Measurement

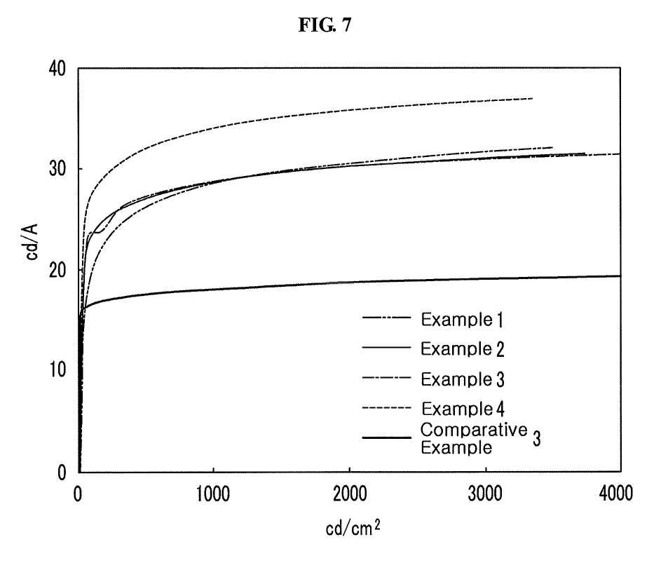

The luminance and current density obtained in the above (1) and (2) and a voltage were used to calculate current efficiency (cd/A) and electric power efficiency (lm/W) at the same current density (10 mA/cm²). The results are shown in the following Table 2 and FIG. 7.

(4) Color coordinates were measured with a luminance meter (Minolta Cs-100A), and the measurement results were shown in the following Table 2.

(5) Life-spans were shown in the following Table 2 by measuring the time taken until the initial luminance was reduced by 50% from 1000 cd/m².

TABLE 2

| | | At 1000 cd/m² | | | |
|---|---|---|---|---|---|
| | Host | | Current | Electric | |
| | compound | Driving | ef- | power ef- | Color |
| | (weight | voltage | ficiency | ficiency | coordinate |
| | ratio) | (V) | (cd/A) | (lm/W) | (x, y) |
| Example 1 | Prep. Ex. 1: | 4.9 | 28.5 | 18.2 | 0.339, 0.622 |
| | Prep. Ex. 3 | | | | |
| | (1:1) | | | | |
| Example 2 | Prep. Ex. 2: | 5.1 | 28.8 | 17.6 | 0.341, 0.620 |
| | Prep. Ex. 3 | | | | |
| | (1:1) | | | | |
| Example 3 | Prep. Ex. 1: | 5.1 | 28.8 | 17.9 | 0.340, 0.621 |
| | Prep. Ex. 4 | | | | |
| | (1:1) | | | | |
| Example 4 | Prep. Ex. 2: | 5.2 | 33.9 | 20.7 | 0.343, 0.618 |
| | Prep. Ex. 4 | | | | |
| | (1:1) | | | | |
| Comparative | Prep. Ex. 1 | 12.2 | 4.4 | 1.1 | 0.318, 0.613 |
| Example 1 | | | | | |
| Comparative | Prep. Ex. 2 | 9.8 | 11.2 | 3.6 | 0.313, 0.616 |
| Example 2 | | | | | |
| Comparative | PVK:PBD | 4.5 | 18.1 | 12.6 | 0.326, 0.627 |
| Example 3 | (1:1) | | | | |

It may be seen from Table 2 that the luminous efficiency of Comparative Examples 1 and 2 (each of which used a single host compound) was lower than 15 cd/A.

In the case of Comparative Example 3, a device was manufactured by mixing PBD, which is a low-molecular material having an electron transport property, and PVK, which is a polymer having a hole transport property, and a relatively higher luminous efficiency of 18 cd/A was shown.

In comparison, the results of Examples 1 to 4 (where the host compounds synthesized according to Preparation Examples 1 to 4 were mixed and used) showed excellent device performance, which included decreased driving voltage and improved luminous efficiency and electric power efficiency.

By way of summation and review, a dopant along with a host material may be included in an emission layer to increase efficiency and stability of an organic light emitting diode. For the host material, 4,4-N,N-dicarbazolebiphenyl (CBP) as a green phosphorescent dopant, an organic compound including carbazole such as 1,3-bis(carbazol-9-yl)benzene (MCP) as a blue phosphorescent dopant, or an organic metal compound such as an aluminum (Al) complex compound or a beryllium (Be) complex compound as a red phosphorescent dopant may be considered. However, these low molecular host materials may have low solubility and may be easily crystallized after forming a film, and therefore may be difficult to apply to a wet process.

To realize an organic photoelectric device with excellent efficiency and life-span, a host material having excellent electrical stability and bipolar characteristics (providing good transportation of both holes and electrons) may be useful.

As described above, an embodiment provides a composition for an organic photoelectric device that may be capable of transporting holes and electrons well. Another embodiment provides an organic photoelectric device that may exhibit excellent efficiency, driving voltage, and life-span characteristics. The organic photoelectric device may include the composition for an organic photoelectric device according to an embodiment. Yet another embodiment provides a display device including the organic photoelectric device.

The composition for an organic photoelectric device according to an embodiment may be suitable for a wet process, and particularly, may be applied to an organic thin layer of an organic photoelectric device, and may provide an organic photoelectric device and a display device having high luminous efficiency at a low voltage and improved life-span.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope as set forth in the following claims.

What is claimed is:

1. A composition for an organic photoelectric device, the composition comprising:
a first host compound including substituents represented by the following Chemical Formulas 1 to 3 sequentially combined; and
a second host compound represented by the following Chemical Formula 4, 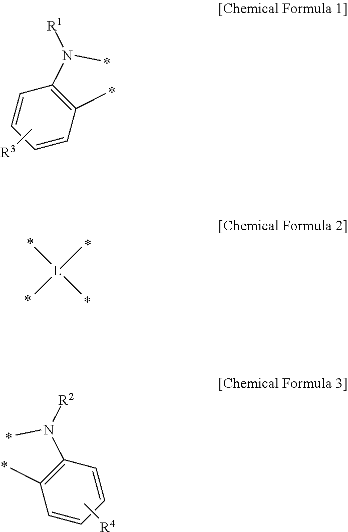
wherein, in the above Chemical Formulas 1 to 3,
L is a C2 or C3 alkenylene or a C6 to C12 arylene,
R¹ and R² are each independently an amine group, a carbazolyl group, a C1 to C30 alkyl group, a C6 to C30 aryl group, or a combination thereof, and
R³ and R⁴ are each independently hydrogen, an amine group, a carbazolyl group, a C1 to C30 alkyl group, a C6 to C30 aryl group, or a combination thereof; 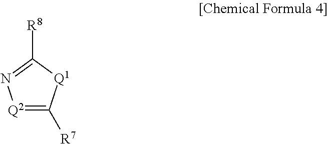
wherein, in the above Chemical Formula 4,
Q¹ is O or NR⁵, wherein R⁵ is a C1 to C60 alkyl group, a C6 to C60 aryl group, or a combination thereof,
Q² is N or CR⁶, wherein R⁶ is a C1 to C60 alkyl group, a C1 to C60 alkylene group, a C2 to C60 alkenyl group, a C2 to C60 alkenylene group, a C6 to C60 aryl group, a C6 to C60 arylene group, or a combination thereof, or R⁶ is linked to R⁷ to form a fused ring,
R⁷ is an amine group, a carbazolyl group, a fluorenyl group, a fluorenylene group, a C1 to C60 alkyl group, a C1 to C60 alkylene group, a C2 to C60 alkenyl group, a C2 to C60 alkenylene group, a C6 to C60 aryl group, a C6 to C60 arylene group, a C3 to C60 heteroaryl group, a C3 to C60 heteroarylene group, or a combination thereof, and
R⁸ is an amine group, a carbazolyl group, a fluorenyl group, a C1 to C60 alkyl group, a C6 to C60 aryl group, or a combination thereof.

2. The composition as claimed in claim 1, wherein the substituent represented by the above Chemical Formula 2 is represented by one or more of the following Chemical Formulas 2a to 2c: 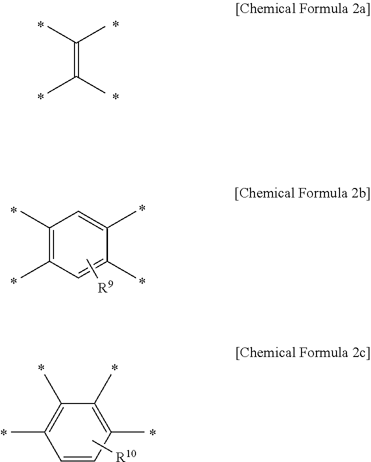
wherein, in the above Chemical Formulas 2a to 2c,
R⁹ and R¹⁰ are each independently hydrogen, an amine group, a carbazolyl group, a C1 to C30 alkyl group, a C6 to C30 aryl group, or a combination thereof.

3. The composition as claimed in claim 1, wherein the first host compound is represented by one or more of the following Chemical Formulas 6 to 12: 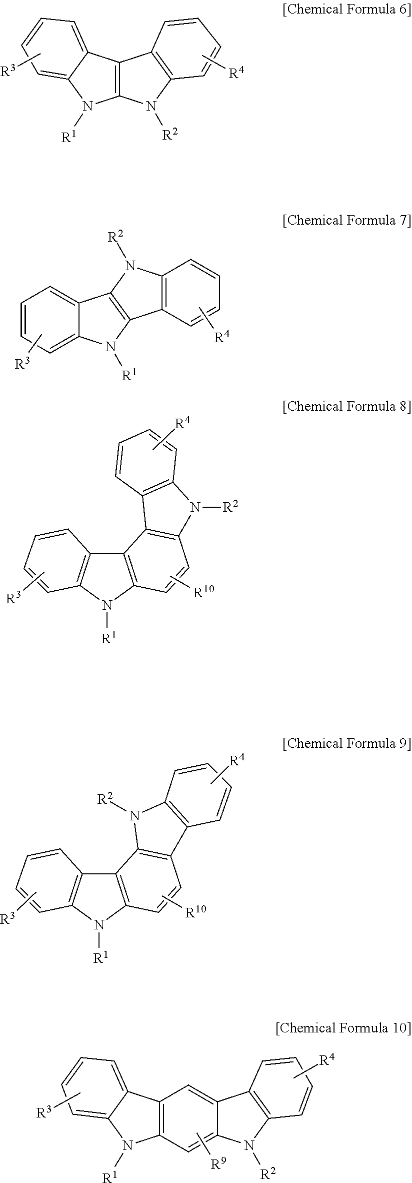 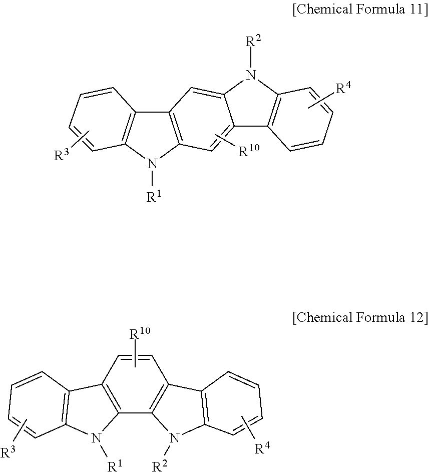
wherein, in the above Chemical Formulas 6 to 12,
R¹ and R² are each independently an amine group, a carbazolyl group, a C1 to C30 alkyl group, a C6 to C30 aryl group, or a combination thereof, and
R³, R⁴, R⁹ and R¹⁰ are each independently hydrogen, an amine group, a carbazolyl group, a C1 to C30 alkyl group, a C6 to C30 aryl group, or a combination thereof.

4. The composition as claimed in claim 1, wherein the first host compound is represented by one or more of the following Chemical Formulas 13 to 42.

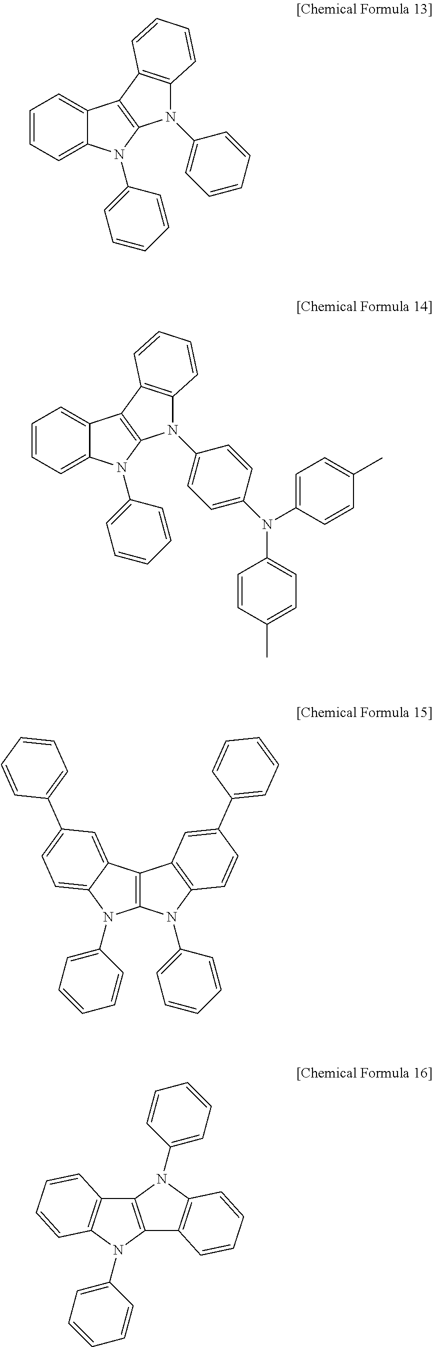

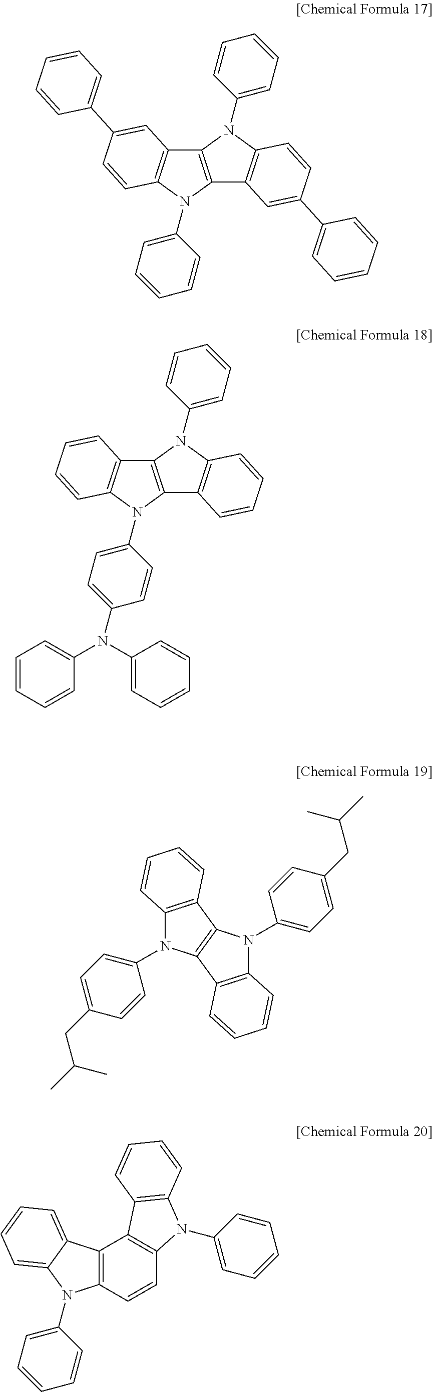

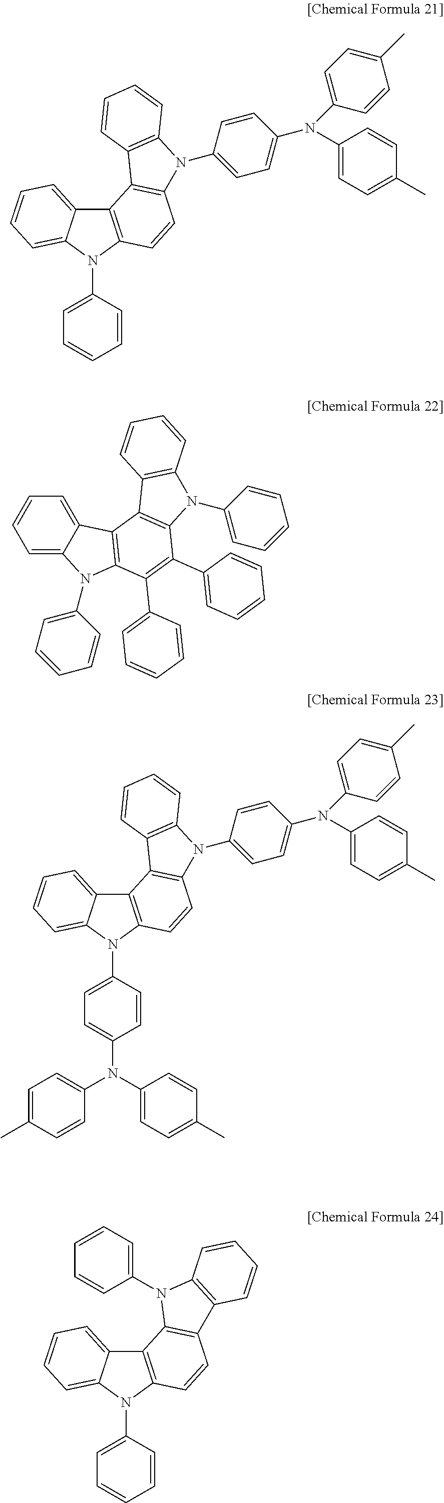

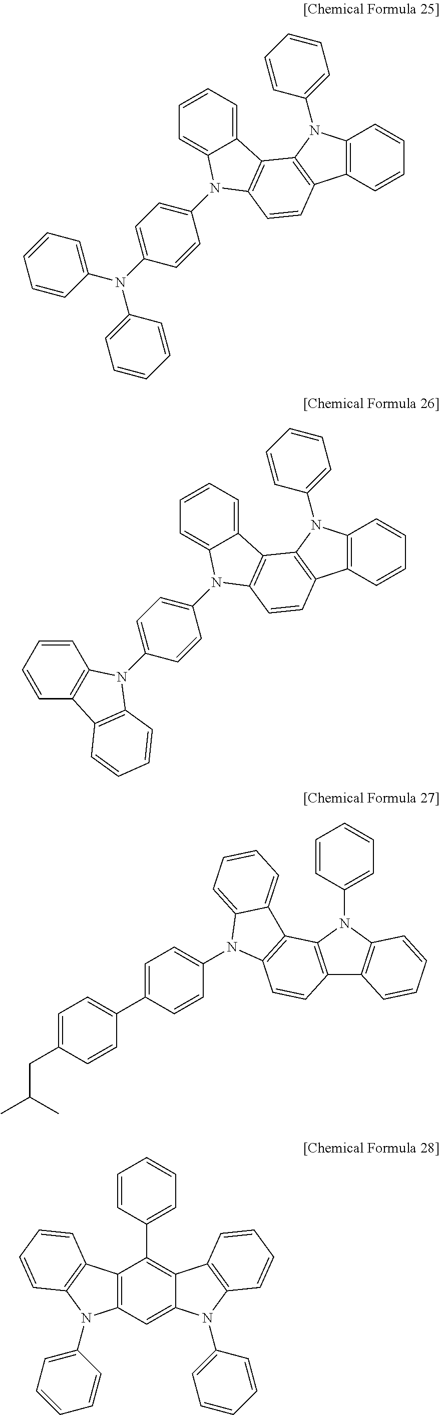

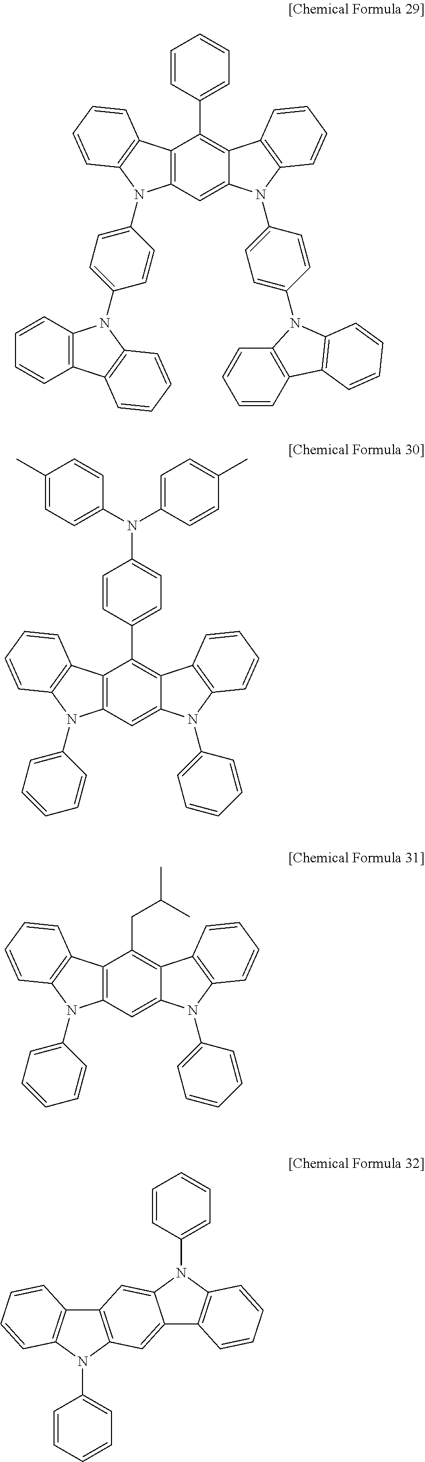

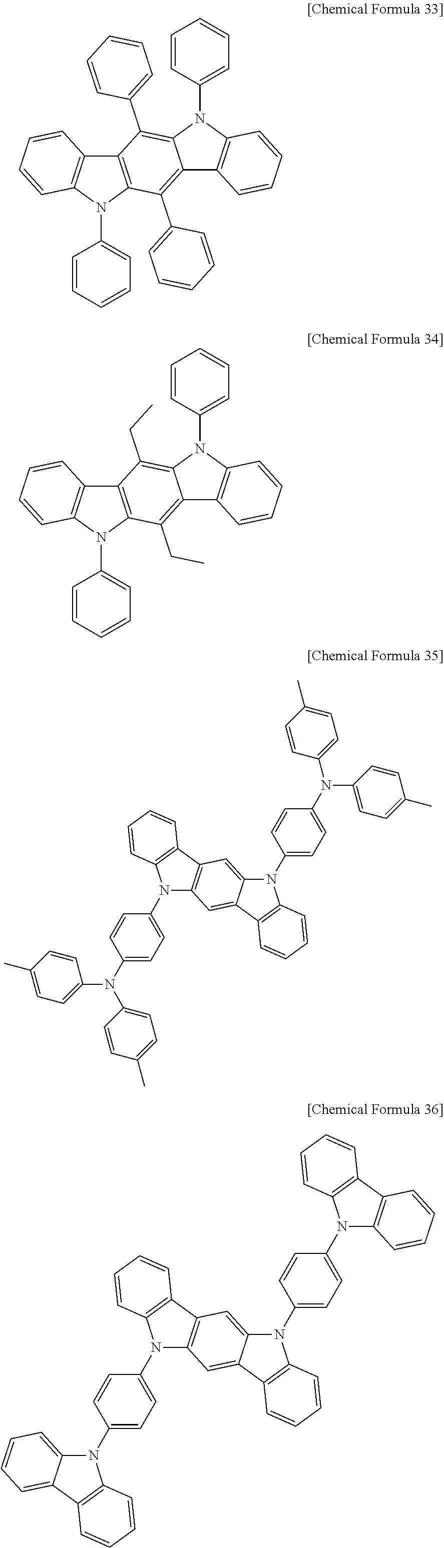

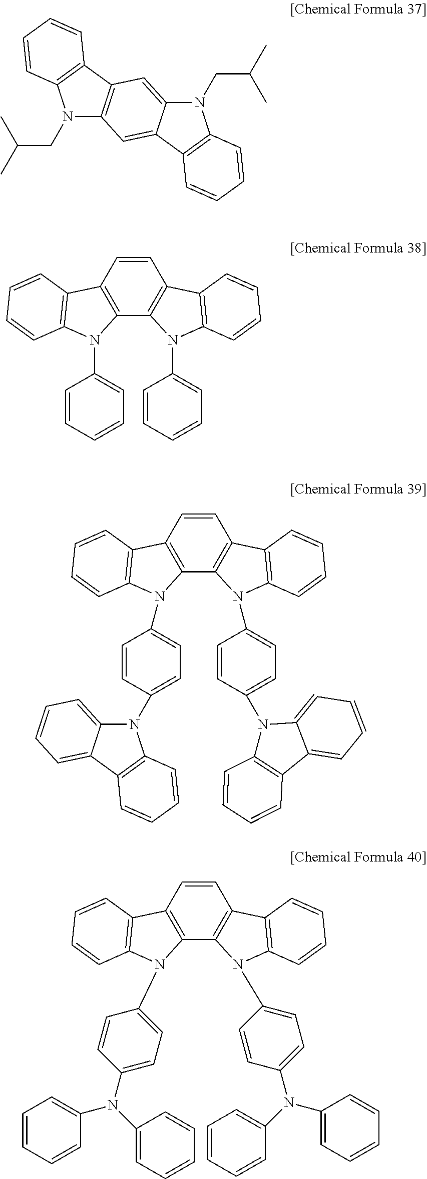

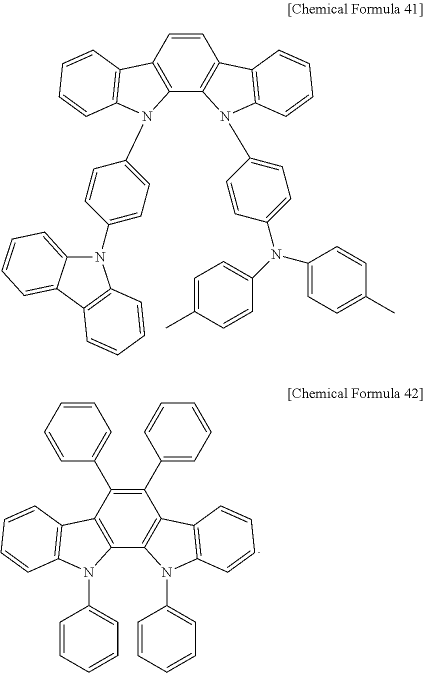

5. The composition as claimed in claim 1, wherein the second host compound represented by the above Chemical Formula 4 is represented by one or more of the following Chemical Formulas 4a to 4b: 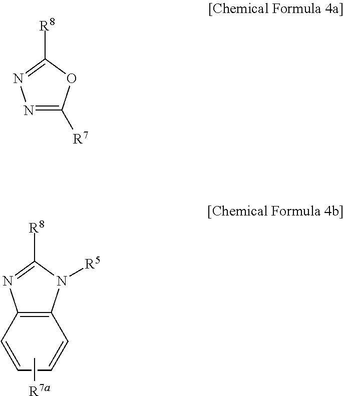
wherein, in Chemical Formulas 4a to 4b,
R⁵ is a C1 to C60 alkyl group, a C6 to C60 aryl group, or a combination thereof,
R⁷ and R^{7a} are each independently an amine group, a carbazolyl group, a fluorenyl group, a C1 to C60 alkyl group, a C2 to C60 alkenyl group, a C6 to C60 aryl group, a C3 to C60 heteroaryl group, or a combination thereof, and
R⁸ is an amine group, a carbazolyl group, a fluorenyl group, a C1 to C60 alkyl group, a C6 to C60 aryl group, or a combination thereof.

6. The composition as claimed in claim 1, wherein the second host compound represented by the above Chemical Formula 4 is represented by the following Chemical Formula 4c: 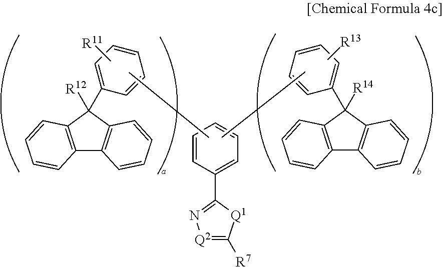
wherein, in the above Chemical Formula 4c,
Q¹ is O or NR⁵, wherein R⁵ is a C1 to C60 alkyl group, a C6 to C60 aryl group, or a combination thereof,
Q² is N or CR⁶, wherein R⁶ is a C1 to C60 alkyl group, a C1 to C60 alkylene group, a C2 to C60 alkenyl group, a C2 to C60 alkenylene group, a C6 to C60 aryl group, a C6 to C60 arylene group, or a combination thereof, or R⁶ is linked to R⁷ to form a fused ring,
R⁷ is an amine group, a carbazolyl group, a fluorenyl group, a fluorenylene group, a C1 to C60 alkyl group, a C1 to C60 alkylene group, a C2 to C60 alkenyl group, a C2 to C60 alkenylene group, a C6 to C60 aryl group, a C6 to C60 arylene group, a C3 to C60 heteroaryl group, a C3 to C60 heteroarylene group, or a combination thereof,
R¹¹ to R¹⁴ are each independently a C1 to C60 alkyl group, a C1 to C60 alkylene group, a C2 to C60 alkenyl group, a C2 to C60 alkenylene group, a C6 to C60 aryl group, a C6 to C60 arylene group, or a combination thereof, or R¹¹ is linked to R¹² to form a fused ring, or R¹³ is linked to R¹⁴ to form a fused ring, and
a and b are the same or different and are each independently 0 or 1, provided that a+b is an integer of greater than or equal to 1.

7. The composition as claimed in claim 1, wherein the second host compound is represented by one or more of the following Chemical Formulas 43 to 46.

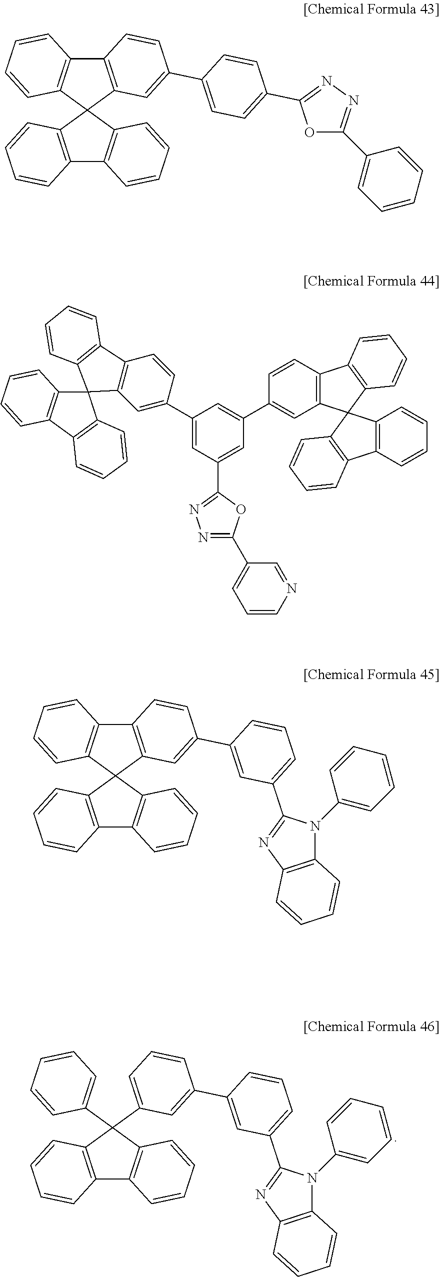

8. The composition as claimed in claim 1, wherein the composition includes the first host compound and the second host compound at a weight ratio of about 50:1 to about 50:2,500.

9. An organic photoelectric device, comprising:
an anode, a cathode, and an organic thin layer, the organic thin layer being between the anode and the cathode, the organic thin layer including the composition as claimed in claim 1.

10. The organic photoelectric device as claimed in claim 9, wherein the composition is present as a phosphorescent host material.

11. The organic photoelectric device as claimed in claim 10, wherein the composition is present in an emission layer.

12. The organic photoelectric device as claimed in claim 11, wherein the emission layer further comprises a dopant.

13. The organic photoelectric device as claimed in claim 12, wherein the dopant is a red, green, or blue phosphorescent dopant.

14. The organic photoelectric device as claimed in claim 11, wherein the organic thin layer includes the emission layer and includes at least one other layer between the anode and the cathode, the at least one other layer being selected from the group of a hole transport layer, a hole injection layer, a hole blocking layer, an electron transport layer, an electron injection layer, an electron blocking layer, and a combination thereof.

15. A display device comprising the organic photoelectric device as claimed in claim 9.
